(19) United States
(12) Patent Application Publication
(10) Pub. No.: US 2026/0215089 A1
(43) Pub. Date: Jul. 23, 2026

(54) DISPLAY DEVICE AND ELECTRONIC DEVICE INCLUDING THE SAME

(71) Applicant: Samsung Display Co., LTD., Yongin-si (KR)

(72) Inventors: Jong Hyun CHOI, Yongin-si (KR); Min Soo KIM, Yongin-si (KR)

(21) Appl. No.: 19/300,003

(22) Filed: Aug. 14, 2025

(30) Foreign Application Priority Data
Jan. 21, 2025 (KR) 10-2025-0008569

(51) Int. Cl. H10K 59/121; H10K 59/122; H10K 59/131; H10K 59/38; H10K 59/80

(52) U.S. Cl. CPC H10K 59/1213; H10K 59/122; H10K 59/131; H10K 59/38; H10K 59/80524; H10K 59/873; H10K 59/8792

(57) ABSTRACT

A display device includes, a first display area and a second display area surrounded by the first display area, a substrate, a first pixel circuit and a second pixel circuit located on the substrate and each including a thin-film transistor, a first pixel electrode and a second pixel electrode located on the first pixel circuit and the second pixel circuit, respectively, and located in the first display area and the second display area, respectively, a light emitting layer located on each of the first pixel electrode and the second pixel electrode, a common electrode located on the light emitting layer, a first transmission portion defined in the second display area and not overlapping the second pixel electrode, and a second transmission portion defined through the second pixel electrode.

This application claims priority to Korean Patent Application No. 10-2025-0008569, filed on Jan. 21, 2025, and all the benefits accruing therefrom under 35 U.S.C. § 119, the content of which in its entirety is herein incorporated by reference.

### BACKGROUND

### 1. Field

The present disclosure relates to a display device and an electronic device including the display device.

### 2. Description of the Related Art

As the information society develops, demands for display devices for displaying images are increasing in various forms. For example, display devices are applied to various electronic devices such as smartphones, digital cameras, notebook computers, navigation systems, and smart televisions.

A display device may include various optical devices such as an image sensor for capturing an image of a front surface of the display device, a proximity sensor for determining the presence of a user at the front of the display device, an illumination sensor for sensing the illumination at the front of the display device, and an iris sensor for recognizing the user's iris.

As display devices are applied to various electronic devices, display devices with various designs are desired. For example, smartphones may be desired to include a display device which can expand a display area by removing a hole from a front surface of the display device. In this case, an optical device, which used to be located in the hole of the front surface of the display device, may overlap a display panel.

### SUMMARY

Embodiments of the present disclosure provide a display device, which improves the transmittance of a sub-display area, and an electronic device including the display device.

Embodiments of the present disclosure also provide a display device, which improves the uniformity of light incident on a sub-display area, and an electronic device including the display device.

However, embodiments of the present disclosure are not limited to the one set forth herein. The above and other embodiments of the present disclosure will become more apparent to one of ordinary skill in the art to which the present disclosure pertains by referencing the detailed description of the present disclosure given below.

According to an embodiment of the present disclosure, a display device includes a first display area and a second display area surrounded by the first display area, a substrate, a first pixel circuit and a second pixel circuit which are located on the substrate, where each of the first pixel circuit and the second pixel circuit includes a thin-film transistor, a first pixel electrode and a second pixel electrode which are located on the first pixel circuit and the second pixel circuit, respectively, and located in the first display area and the second display area, respectively, a light emitting layer located on each of the first pixel electrode and the second pixel electrode, a common electrode located on the light emitting layer, a first transmission portion defined in the second display area and not overlapping the second pixel electrode, and a second transmission portion defined through the second pixel electrode.

In an embodiment, the second pixel electrode may be provided with a first opening overlapping the second transmission portion.

In an embodiment, the display device may further include a bottom conductive layer located between the second pixel circuit and the substrate, where the bottom conductive layer may include a bottom conductive pattern overlapping the second pixel electrode, and the bottom conductive pattern may be provided with a second opening overlapping the second transmission portion.

In an embodiment, the light emitting layer may be provided with a third opening overlapping the second transmission portion.

In an embodiment, the common electrode may be provided with a fourth opening overlapping the second transmission portion.

In an embodiment, the display device may further include a thin-film encapsulation layer located on the common electrode, where the thin-film encapsulation layer covers side surfaces of the second pixel electrode within the first opening.

In an embodiment, the display device may further include a color filter located on the common electrode, where the color filter may be provided with a fifth opening overlapping the second transmission portion.

In an embodiment, a density of the first pixel electrode in the first display area may be higher than a density of the second pixel electrode in the second display area.

In an embodiment, the display device may further include at least one insulating layer located under the first pixel electrode and the second pixel electrode, where the at least one insulating layer may be located across the first display area and the second display area, and may not overlap the first transmission portion.

In an embodiment, the at least one insulating layer may be provided with a seventh opening overlapping the second transmission portion and penetrating the at least one insulating layer.

In an embodiment, the display device may further include a bottom conductive layer which is located between the substrate and the second pixel circuit and includes a bottom conductive pattern located under the second pixel circuit, where a through hole overlapping the second pixel electrode may be defined through the at least one insulating layer, the bottom conductive layer may further include a contact electrode extending across the first display area and the second display area to overlap the second pixel electrode, and the second pixel electrode may be located within the through hole and directly contact the contact electrode within the through hole.

In an embodiment, the display device may further include a source-drain conductive layer which is located between the first pixel circuit and the first pixel electrode and includes a first connection electrode connecting the first pixel circuit and the first pixel electrode, where the source-drain conductive layer may further include a second connection electrode which connects the second pixel circuit and the contact electrode.

In an embodiment, the display device may further include lines connected to at least one of the first pixel circuit and the second pixel circuit and extending across the first display area and the second display area, where the lines may not overlap the second transmission portion.

In an embodiment, the display device may further include a pixel defining layer located on the first pixel electrode and the second pixel electrode and provided with first openings which overlap the first pixel electrode and the second pixel electrode, a light blocking layer located on the common electrode and provided with second openings which overlap the first openings, and color filters overlapping the second openings, where at least a portion of the light emitting layer is located in the first openings, the color filters may not overlap the second transmission portion, the light blocking layer may include a first portion overlapping the pixel defining layer and a second portion overlapping the second pixel electrode, and second portion may be provided with a sixth opening overlapping the second transmission portion.

According to an embodiment of the present disclosure, a display device includes a first display area, a second display area surrounded by the first display area, and a third display area surrounded by the second display area, a substrate, a first pixel circuit, a second pixel circuit and a third pixel circuit which are located on the substrate, where each of the first pixel circuit, the second pixel circuit and the third pixel circuit includes a thin-film transistor, a first pixel electrode, a second pixel electrode and a third pixel electrode which are located on the first pixel circuit, the second pixel circuit and the third pixel circuit, respectively, and located in the first display area, the second display area and the third pixel display area, respectively, a light emitting layer located on each of the first pixel electrode, the second pixel electrode, and the third pixel electrode, a common electrode located on the light emitting layer, a first transmission portion defined in the third display area and not overlapping the second pixel electrode, and a second transmission portion defined through the third pixel electrode, where the first pixel circuit is located in the first display area, the second pixel circuit and the third pixel circuit are located in the second display area, the second pixel circuit is connected to the second pixel electrode by a first connection electrode located in the second display area, and the third pixel circuit is connected to the third pixel electrode by a second connection electrode located across the second display area and the third display area.

In an embodiment, the second pixel electrode may include a first sub-pixel electrode and a first copy pixel electrode, the first sub-pixel electrode and the first copy pixel electrode may be connected to each other by a first bridge electrode, and the first sub-pixel electrode, the first copy pixel electrode and the first bridge electrode may be integrally formed with each other as a single unitary indivisible part.

In an embodiment, the third pixel electrode may include a second sub-pixel electrode and a second copy pixel electrode, the second sub-pixel electrode and the second copy pixel electrode may be connected to each other by a connection pattern, and the connection pattern may be an electrode separated from the second sub-pixel electrode and the second copy pixel electrode.

In an embodiment, the second connection electrode may include a transparent electrode.

According to an embodiment of the present disclosure, an electronic device includes a display device, and a processor which provides a data signal to the display device, where the display device includes a first display area and a second display area surrounded by the first display area, a substrate, a first pixel circuit and a second pixel circuit which are located on the substrate, where each of the first pixel circuit and the second pixel circuit includes a thin-film transistor, a first pixel electrode and a second pixel electrode which are located on the first pixel circuit and the second pixel circuit, respectively and located in the first display area and the second display area, respectively, a light emitting layer located on the first pixel electrode and the second pixel electrode, a common electrode located on the light emitting layer, a first transmission portion defined in the second display area and not overlapping the second pixel electrode, and a second transmission portion defined through the second pixel electrode.

According to an embodiment of the present disclosure, an electronic device includes a display device, and a processor which provides a data signal to the display device, where the display device includes a first display area, a second display area surrounded by the first display area, and a third display area surrounded by the second display area, a substrate, a first pixel circuit, a second pixel circuit and a third pixel circuit which are located on the substrate, where each of the first pixel circuit, the second pixel circuit and the third pixel circuit includes a thin-film transistor, a first pixel electrode, a second pixel electrode and a third pixel electrode which are located on the first pixel circuit, the second pixel circuit and the third pixel circuit, respectively, and located in the first display area, the second display area and the third pixel display area, respectively, a light emitting layer located on each of the first pixel electrode, the second pixel electrode, and the third pixel electrode, a common electrode located on the light emitting layer, a first transmission portion defined in the third display area and not overlapping the second pixel electrode, and a second transmission portion defined through the third pixel electrode, where the first pixel circuit is located in the first display area, the second pixel circuit and the third pixel circuit are located in the second display area, the second pixel circuit is connected to the second pixel electrode by a first connection electrode located in the second display area, and the third pixel circuit is connected to the third pixel electrode by a second connection electrode located across the second display area and the third display area.

In a display device and an electronic device including the display device according to an embodiment of the present disclosure, the transmittance of a sub-display area can be improved.

In a display device and an electronic device including the display device according to an embodiment of the present disclosure, the uniformity of light incident on a sub-display area can be improved.

However, the effects of embodiments of the present disclosure are not limited to the one set forth herein. The above and other effects of embodiments of the present disclosure will become more apparent to one of daily skill in the art to which the present disclosure pertains by referencing the detailed description of the present disclosure given below.

### BRIEF DESCRIPTION OF THE DRAWINGS

These and/or other features of embodiments of the disclosure will become apparent and more readily appreciated from the following description of embodiments thereof, taken in conjunction with the accompanying drawings, in which:

FIG. 1 is a perspective view of a display device according to an embodiment;

FIG. 2 is a plan view of the display device according to an embodiment;

FIG. 3 is a cross-sectional view of the display device taken along line X1-X1′ of FIG. 2;

FIG. 4 is a block diagram illustrating a display panel and a display driver according to an embodiment;

FIG. 5 is an enlarged view of area A of FIG. 2;

FIG. 6 is a plan view of a sub-display area according to an embodiment;

FIG. 7 is a plan view of an example of a sub-display pixel according to an embodiment;

FIG. 8 is a plan view of another example of the sub-display pixel according to an embodiment;

FIG. 9 is a plan view of another example of the sub-display pixel according to an embodiment;

FIG. 10 is a plan view of another example of the sub-display pixel according to an embodiment;

FIG. 11 is a plan view of another example of the sub-display pixel according to an embodiment;

FIG. 12 is a plan view of another example of the sub-display pixel according to an embodiment;

FIG. 13 is a cross-sectional view of the sub-display area of the display device taken along line X2-X2′ of FIG. 6;

FIG. 14 is a cross-sectional view of a sub-display area of a display device according to an embodiment;

FIG. 15 is a cross-sectional view of a sub-display area of a display device according to an embodiment;

FIG. 16 is a plan view illustrating the arrangement of pixel electrodes in each main pixel of a display device according to an embodiment;

FIG. 17 is a plan view illustrating the arrangements of pixel electrodes in sub-pixels of the display device according to the embodiment of FIG. 16;

FIG. 18 is a cross-sectional view of a sub-display area of the display device according to the embodiment of FIG. 16;

FIG. 19 is a cross-sectional view illustrating a main display area and a sub-display area of a display device according to an embodiment;

FIG. 20 is a cross-sectional view illustrating a main display area and a sub-display area of a display device according to an embodiment;

FIG. 21 is a block diagram of an electronic device according to an embodiment; and

FIG. 22 is a schematic diagram of electronic devices according to various embodiments.

### DETAILED DESCRIPTION

The invention will now be described more fully hereinafter with reference to the accompanying drawings, in which preferred embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will also be understood that when a layer is referred to as being “on” another layer or substrate, it can be directly on the other layer or substrate, or intervening layers may also be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the present disclosure will be described in detail with reference to the accompanying drawings.

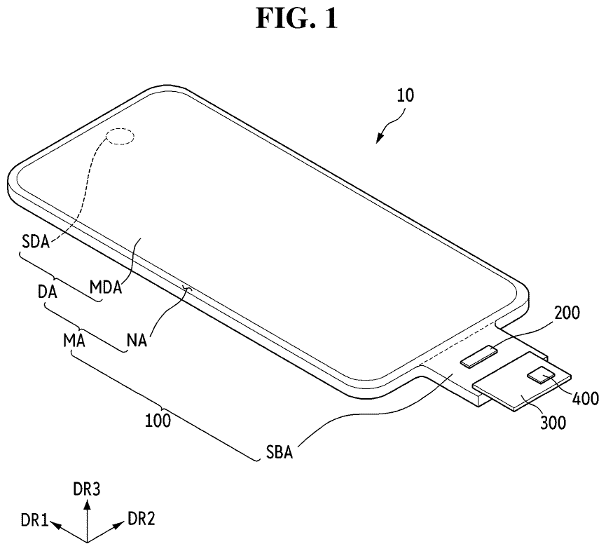

FIG. 1 is a perspective view of a display device 10 according to an embodiment.

Referring to FIG. 1, an embodiment of the display device 10 is a device for displaying moving images or still images. The display device 10 may be used as a display screen in portable electronic devices such as mobile phones, smartphones, tablet personal computers (PCs), smart watches, watch phones, mobile communication terminals, electronic notebooks, electronic books, portable multimedia players (PMPs), navigation devices and ultra-mobile PCs (UMPCs), as well as in various products such as televisions, notebook computers, monitors, billboards and Internet of things (IoT) devices.

In an embodiment, the display device 10 may be a light emitting display device such as an organic light emitting display device including an organic light emitting diode, a quantum dot light emitting display device including a quantum dot light emitting layer, an inorganic light emitting display device including an inorganic semiconductor, or a micro-or nano-light emitting display device using a micro-or nano-light emitting diode. Hereinafter, for convenience of description, embodiments in which the display device 10 is an organic light emitting display device will be mainly described, but the type of the display device 10 is not limited to an organic light emitting display device.

In an embodiment, the display device 10 may be formed flat. In an embodiment, for example, the display device 10 may be formed substantially flat on a plane defined by a first direction DR1 and a second direction DR2 and may have a selected thickness (or height) in a third direction DR3. In an embodiment, the display device 10 may include a curved portion in at least one part such as an edge area. Alternatively, the display device 10 may be formed to be flexible so that the display device 10 can be bent, curved, folded, or rolled.

In an embodiment, the first direction DR1 may be a lengthwise direction, a column direction or a vertical direction of an image display surface of the display device 10, and the second direction DR2 may be a direction intersecting the first direction DR1, for example, may be a widthwise direction, a row direction or a horizontal direction. The third direction DR3 may be a thickness direction or a height direction of the display device 10.

In an embodiment, as shown in FIG. 1, the display device 10 may include a display panel 100, a display driver 200, a circuit board 300, and a touch driver 400.

The display panel 100 may include a main area MA including a display area DA where an image is displayed and a sub-area SBA located on a side of the main area MA.

The main area MA may include the display area DA and a non-display area NA around the display area DA. The display area DA may be located in a center of the main area MA and may occupy most of the main area MA. The non-display area NA may be located at edges of the main area MA and may contact the sub-area SBA.

The display area DA may be an area where pixels are arranged and where an image is displayed by the pixels. In an embodiment, sensing patterns (e.g., touch electrodes) for detecting a touch input or the like may be further provided in the display area DA, and the display area DA may include a sensing area where a touch input is detected by the sensing patterns.

In an embodiment, the display area DA may be shaped or have a planar shape like a substantially rectangular plane having long sides in the first direction DR1 and short sides in the second direction DR2. Each corner where a long side and a short side of the display area DA meet may be rounded or right-angled. The shape of the display area DA may vary according to embodiments. In another embodiment, for example, the display area DA may also have a polygonal shape other than a quadrangular shape, a circular shape, or an elliptical shape.

The display area DA may include a main display area MDA and a sub-display area SDA. The sub-display area SDA is an area where components for adding various functions to the display device 10 are placed. The sub-display area SDA may correspond to a component area.

The non-display area NA may be located immediately around the display area DA. The non-display area NA may surround the display area DA. An embedded circuit may be located in the non-display area NA. In an embodiment, for example, an embedded circuit including a scan driving circuit may be located in the non-display area NA on one side (e.g., a left or right side) or opposite sides of the display area DA.

The sub-area SBA may be located on a side of the main area MA. In an embodiment, for example, the sub-area SBA may be an area protruding from a side of the main area MA in the first direction DR1. In an embodiment, for example, the sub-area SBA may protrude from a lower end of the main area MA in the first direction DR1. In an embodiment, the sub-area SBA may be narrower than the main area MA. In an embodiment, for example, the sub-area SBA may be narrower than the main area MA in the second direction DR2.

Lines and pads may be located in the sub-area SBA. In an embodiment, for example, lines and pads, which are connected to pixels and/or an embedded circuit located in the main area MA and the display driver 200 and/or the circuit board 300 located in the sub-area SBA, may be located in the sub-area SBA. In the description of embodiments, the term “connect” may mean electrical connection and/or physical connection.

In an embodiment, the display driver 200 (e.g., a display driving circuit) may be mounted in the sub-area SBA. The circuit board 300 may be located on a portion of the sub-area SBA.

The display driver 200 may include a data driving circuit for driving pixels. In an embodiment, the display driver 200 may be formed (or defined) as an integrated circuit and placed in the sub-area SBA. In an embodiment, the display driver 200 may be placed on the circuit board 300 on the sub-area SBA or may be placed on another circuit board which is connected to the display panel 100 through the circuit board 300.

The circuit board 300 may be placed on a portion of the sub-area SBA. In an embodiment, for example, the circuit board 300 may be bonded onto pads located in a portion (e.g., a lower edge) of the sub-area SBA and may supply or transmit power voltages and driving signals for driving the display panel 100 to the display panel 100. In an embodiment, for example, the circuit board 300 may supply input image data (e.g., digital image data), driving signals including timing signals, and driving voltages to the display panel 100. The circuit board 300 may be, but is not limited to, a flexible printed circuit board (FPCB), a printed circuit board (PCB), or a flexible film such as a chip on film (COF).

The touch driver 400 may be mounted on the circuit board 300. The touch driver 400 may be connected to a touch sensing unit of the display panel 100. The touch driver 400 may supply a touch driving signal to a plurality of touch electrodes of the touch sensing unit and sense the amount of change in capacitance between the touch electrodes. In an embodiment, for example, the touch driving signal may be a pulse signal having a selected frequency. The touch driver 400 may calculate whether a touch input has occurred and input coordinates based on the amount of change in capacitance between the touch electrodes. The touch driver 400 may be formed as an integrated circuit.

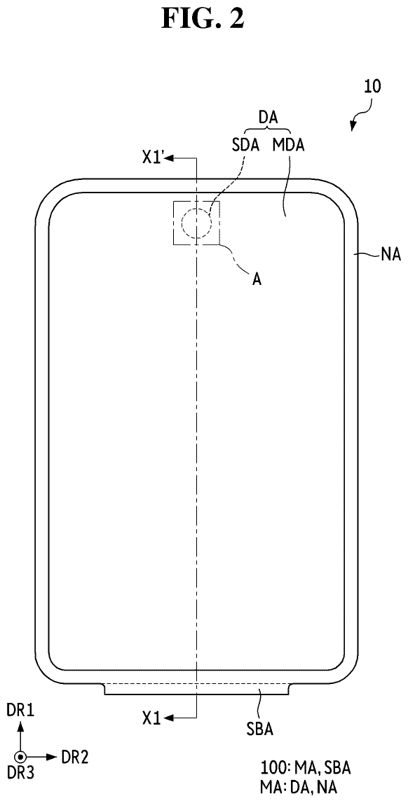

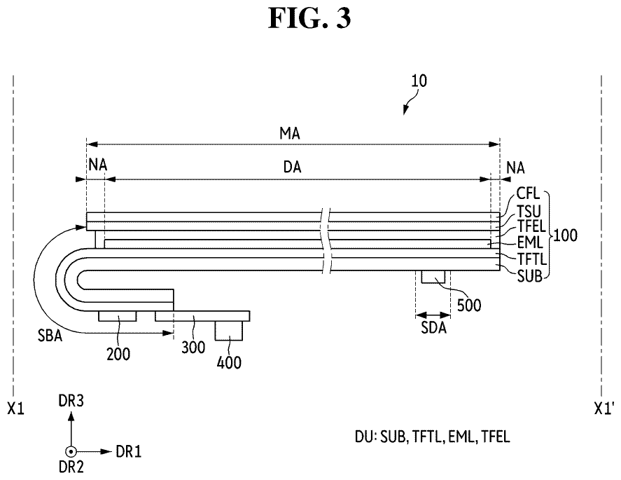

FIG. 2 is a plan view of the display device 10 according to an embodiment. FIG. 3 is a cross-sectional view of the display device 10 taken along line X1-X1′ of FIG. 2.

Referring to FIGS. 2 and 3, an embodiment of the display panel 100 may include a substrate SUB, which includes the main area MA and the sub-area SBA, and a circuit layer TFTL, a light emitting element layer EML, an encapsulation layer TFEL, a touch sensing layer TSU, and a color filter layer CFL which are sequentially located on the substrate SUB. The circuit layer TFTL may be located on the substrate SUB in the main area MA and the sub-area SBA. The light emitting element layer EML and the encapsulation layer TFEL may be located on a portion of the substrate SUB and the circuit layer TFTL. In an embodiment, for example, the light emitting element layer EML and the encapsulation layer TFEL may be located in the main area MA.

In an embodiment, the display device 10 may further include an additional element located on the display panel 100. In an embodiment, for example, the display device 10 may further include at least one of a polarizing layer and a protective layer (e.g., a window) located on the encapsulation layer TFEL. The polarizing layer and/or the protective layer may be manufactured integrally with the display panel 100 or may be manufactured separately from the display panel 100 and then attached to the display panel 100 by an adhesive layer or the like.

The substrate SUB may include an insulating material such as polymer resin. In an embodiment, for example, the substrate SUB may include polyimide or other insulating materials. The substrate SUB may be a flexible substrate that can be bent, folded, or rolled. Alternatively, the substrate SUB may include an insulating material such as glass.

The circuit layer TFTL may include pixel circuits and lines. In an embodiment, for example, the circuit layer TFTL may include circuit elements (e.g., pixel transistors and a capacitor) constituting a pixel circuit of each pixel and lines connected to the pixels. In an embodiment, the circuit layer TFTL may further include circuit elements constituting an embedded circuit, such as a scan driving circuit, and lines connected to the embedded circuit.

The light emitting element layer EML may include light emitting elements located in emission areas of pixels. In an embodiment, for example, each of the pixels may include at least one light emitting element and a pixel circuit connected to the light emitting element. Each of the pixels may be located in a pixel area including an emission area where a light emitting element is located and a pixel circuit area where a pixel circuit is located. The emission area and the pixel circuit area of each pixel may overlap each other, but the present disclosure is not limited to this case.

In embodiments, the circuit layer TFTL and the light emitting element layer EML may be separate from each other. However, the embodiments are not limited to this case. In an embodiment, for example, the circuit layer TFTL and the light emitting element layer EML may also be integrated with each other.

The encapsulation layer TFEL may cover the light emitting element layer EML and extend to the non-display area NA to contact the circuit layer TFTL. In an embodiment, the encapsulation layer TFEL may have a multilayer structure including at least two inorganic encapsulation layers, which overlap each other, and at least one organic encapsulation layer, which is located between the inorganic encapsulation layers. In the disclosure, when two elements are described as overlapping each other, it would be understood that the two elements overlaps each other in the third direction DR3 (or a thickness direction of the display panel 100 or the substrate SUB) as shown in the drawings.

The touch sensing layer TSU may be located on the encapsulation layer TFEL. The touch sensing layer TSU may include a plurality of touch electrodes for sensing a user's touch in a capacitive manner and touch lines connecting the touch electrodes and the touch driver 400. In an embodiment, for example, the touch sensing layer TSU may sense a user's touch in a mutual capacitance manner or a self-capacitance manner.

In an embodiment, the touch sensing layer TSU may be located on a separate substrate located on the display panel 100. In such an embodiment, the substrate supporting the touch sensing layer TSU may be a base member that encapsulates the display panel 100.

The touch electrodes of the touch sensing layer TSU may be located in a touch sensor area overlapping the display area DA. The touch lines of the touch sensing layer TSU may be located in a touch peripheral area overlapping the non-display area NA.

In some embodiments, the display device 10 may further include an optical device 500. The optical device 500 may be located in the sub-display area SDA. The optical device 500 may emit or receive light in an infrared, ultraviolet, or visible light band. In an embodiment, for example, the optical device 500 may be an optical sensor that senses light incident on the display device 10, such as a proximity sensor, an illumination sensor, and a camera sensor or an image sensor.

The color filter layer CFL may be located on the touch sensing layer TSU. The color filter layer CFL may include a plurality of color filters corresponding to a plurality of emission areas, respectively. Each of the color filters may selectively transmit light of a specific wavelength and block or absorb light of other wavelengths. The color filter layer CFL may absorb a portion of light incident thereon from the outside of the display device 10 to reduce reflected light caused by the external light. Therefore, the color filter layer CFL can prevent color distortion caused by reflection of the external light.

The color filter layer CFL may be directly located on the touch sensing layer TSU. Accordingly, the display device 10 may not include a separate substrate for the color filter layer CFL. Therefore, the display panel 100 may have a relatively small thickness.

In an embodiment, the display panel 100 may be bent in a bending area BA. The bending area BA may be a part of the sub-area SBA and may be spaced apart from the main area MA.

The substrate SUB and the circuit layer TFTL may be bent in the bending area BA which corresponds to a part of the sub-area SBA. Accordingly, a bezel area, which is perceived by a user as the non-display area NA, can be reduced or minimized.

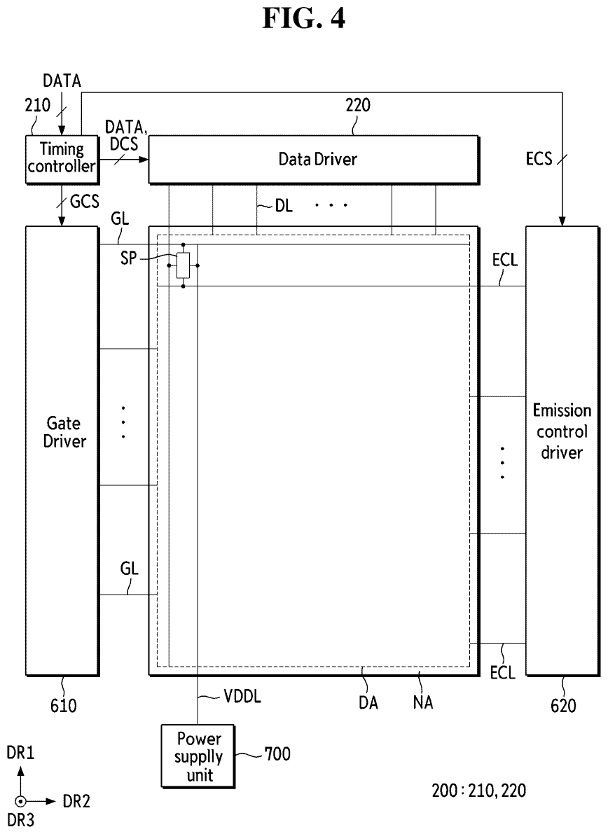

FIG. 4 is a block diagram illustrating a display panel 100 and a display driver 200 according to an embodiment.

Referring to FIG. 4, an embodiment of the display panel 100 may include a display area DA and a non-display area NA. In an embodiment, the display area DA may include pixels SP, driving voltage lines VDDL, gate lines GL, emission control lines ECL, and data lines DL.

Each of the pixels SP may be connected to a gate line GL, a data line DL, an emission control line ECL, and a driving voltage line VDDL. Each of the pixels SP may include at least one transistor, a light emitting element, and a capacitor.

The gate lines GL may extend in the second direction DR2 and may be spaced apart from each other in the first direction DR1 intersecting the second direction DR2. The gate lines GL may sequentially supply a gate signal to the pixels SP.

The emission control lines ECL may extend in the second direction DR2 and may be spaced apart from (or arranged) each other in the first direction DR1. The emission control lines ECL may sequentially supply an emission signal to the pixels SP.

The data lines DL may extend in the first direction DR1 and may be spaced apart from each other (or arranged) in the second direction DR2. The data lines DL may supply a data voltage to the pixels SP. The data voltage may determine the luminance of each of the pixels SP.

The driving voltage lines VDDL may extend in the first direction DR1 and may be spaced apart from each other (or arranged) in the second direction DR2. The driving voltage lines VDDL may supply a driving voltage to the pixels SP. The driving voltage may be a high potential voltage for driving the light emitting elements of the pixels SP.

The display driver 200 may include a timing controller 210 and a data driver 220.

The timing controller 210 may receive digital video data DATA and timing signals from the circuit board 300. The timing controller 210 may supply a gate control signal GCS to a gate driver 610 and an emission control signal ECS to an emission control driver 620. The timing controller 210 may supply the digital video data DATA and a data control signal DCS to the data driver 220. The timing controller 210 may control the operation timing of the data driver 220 by generating the data control signal DCS based on the timing signals, may control the operation timing of the gate driver 610 by generating the gate control signal GCS, and may control the operation timing of the emission control driver 620 by generating the emission control signal ECS.

The data driver 220 may convert the digital video data DATA into analog data voltages and supply the analog data voltages to the data lines DL through fan-out lines. Gate signals of the gate driver 610 may select pixels SP to which the data voltages are to be supplied, and the selected pixels SP may receive the data voltages through the data lines DL.

A power supply unit 700 may be located on the circuit board 300 to supply a power voltage to the display driver 200 and the display panel 100. The power supply unit 700 may generate a driving voltage and supply the driving voltage to a driving voltage line VDDL and may generate a common voltage and supply the common voltage to a common electrode common to the light emitting elements of the pixels SP. The power supply unit 700 may generate an initialization voltage and supply the initialization voltage to an initialization voltage line, may generate a reference voltage and supply the reference voltage to a reference voltage line, and may generate a bias voltage and supply the bias voltage to a bias voltage line.

The gate driver 610 may be located outside one side of the display area DA or on one side of the non-display area NA, and the emission control driver 620 may be located outside the other side of the display area DA or on the other side of the non-display area NA. However, the present disclosure is not limited to this example. In another embodiment, for example, the gate driver 610 and the emission control driver 620 may be located on either one side or the other side of the non-display area NA.

The gate driver 610 may include a plurality of transistors which generate gate signals based on the gate control signal GCS. The emission control driver 620 may include a plurality of transistors which generate emission signals based on the emission control signal ECS. In an embodiment, for example, the transistors of the gate driver 610 and the transistors of the emission control driver 620 may be formed in the same layer as transistors of each of the pixels SP. The gate driver 610 may supply the gate signals to the gate lines GL, and the emission control driver 620 may supply the emission signals to the emission control lines ECL.

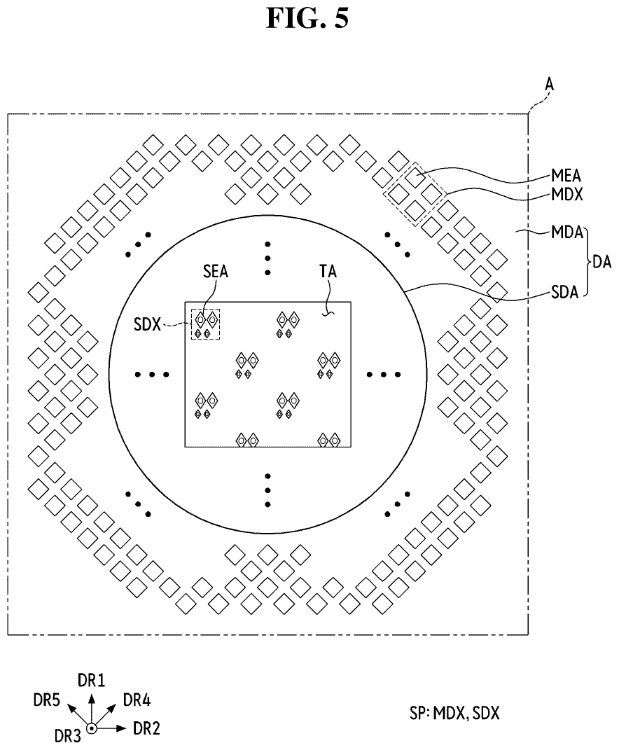

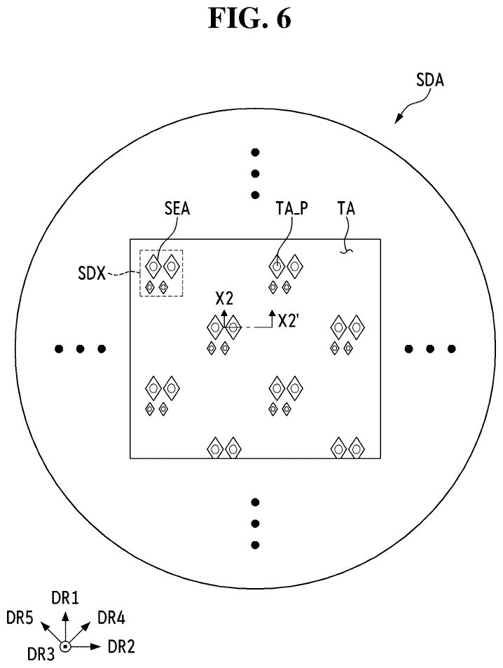

FIG. 5 is an enlarged view of area A of FIG. 2. FIG. 6 is a plan view of a sub-display area SDA according to an embodiment.

Referring to FIG. 5 in addition to FIG. 3, in an embodiment, the display area DA of the display panel 100 may include the main display area MDA and the sub-display area SDA. The sub-display area SDA may be an area where a component is placed under the substrate SUB of the display device 10.

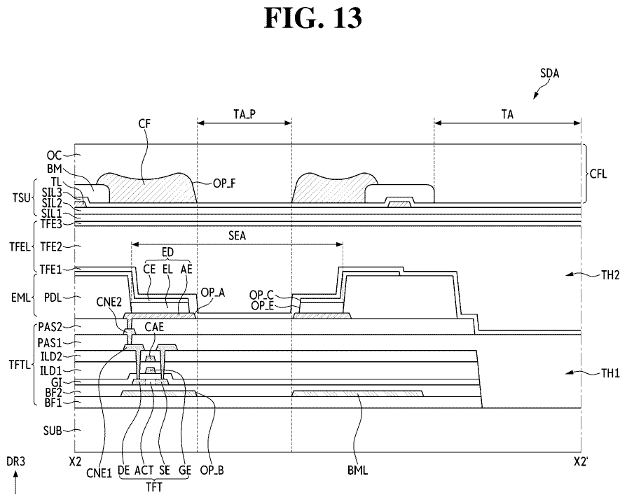

In such an embodiment, pixels SP may include main display pixels MDX located in the main display area MDA and sub-display pixels SDX located in the sub-display area SDA. That is, a plurality of main display pixels MDX may be arranged in the main display area MDA, and a plurality of sub-display pixels SDX may be arranged in the sub-display area SDA. Each of the main display pixels MDX may include one or more main emission areas MEA, and each of the sub-display pixels SDX may include one or more sub-emission areas SEA. A light emitting element ED (see FIG. 13) may be located in each of the emission areas MEA and SEA to emit light.

In the main display area MDA, a plurality of light emitting elements ED (see FIG. 13), which emit light, and pixel circuits, which are electrically connected to the light emitting elements ED (see FIG. 13) and transmit signals for light emission of the light emitting elements ED (see FIG. 13), may be located. The main display area MDA may be an area in which the light emitting elements ED (see FIG. 13) and the pixel circuits are arranged in a specific way or in a predetermined arrangement. In the main display area MDA, the light emitting elements ED (see FIG. 13) may constitute the main emission areas MEA, respectively, and a plurality of main emission areas MEA may constitute one main display pixel MDX. In an embodiment, for example, four main emission areas MEA may constitute one main display pixel MDX. That is, one main display pixel MDX may include four main emission areas MEA, and the four main emission areas MEA may constitute one main display pixel MDX to express a white gray level. However, the number of main emission areas MEA included in a main display pixel MDX is not limited to four.

In some embodiments, the main display pixels MDX located in the main display area MDA may be arranged in a fourth direction DR4 and a fifth direction DR5 which are diagonal directions between the first direction DR1 and the second direction DR2. In addition, the main emission areas MEA of the main display pixels MDX may be arranged in the fourth direction DR4 and the fifth direction DR5.

In the sub-display area SDA, light emitting elements ED (see FIG. 13), which emit light, may also be located. The light emitting elements ED may constitute the sub-emission areas SEA, and a plurality of sub-emission areas SEA may constitute one sub-display pixel SDX. However, the sub-display area SDA may be an area which overlaps, for example, the optical device 500 as a component located on a back surface of the substrate SUB of the display panel 100. Unlike the main display area MDA, the sub-display area SDA may have a structure in which light transmittance is taken into account. In an embodiment, the sub-display area SDA may have a structure having a higher light transmittance than the main display area MDA.

A sub-display pixel SDX, which is formed by a plurality of sub-emission areas SEA of the sub-display area SDA, may have a different arrangement from a main display pixel MDX. In an embodiment, for example, the size and shape of the sub-emission areas SEA included in the sub-display pixel SDX may be different from those of the main emission areas MEA included in the main display pixel MDX.

In addition, since the sub-display area SDA includes a transmission area TA which will be described later, the density of the sub-display pixels SDX in the sub-display area SDA may be lower than the density of the main display pixels MDX in the main display area MDA. Accordingly, the sub-display area SDA may be different in luminance and resolution from the main display area MDA. Here, a density of pixels may refer to the number of the pixels in a unit area in a plan view.

In some embodiments, the sub-display pixels SDX in the sub-display area SDA may be arranged in the fourth direction DR4 and the fifth direction DR5 which are diagonal directions between the first direction DR1 and the second direction DR2.

The sub-display area SDA may further include a transmission area TA (e.g., main transmission portion) which transmit light. The transmission area TA is an area that passes light incident on the display panel 100. In an embodiment, for example, the transmission area TA may be an area where a conductive layer of the circuit layer TFTL, a light emitting element of the light emitting element layer EML, a conductive layer of the touch sensing layer TSU, and a light blocking layer BM (see FIG. 13) and color filters CF (see FIG. 13) of the color filter layer CFL are not located.

The transmission area TA may be located adjacent to the sub-emission areas SEA. The transmission area TA may not overlap the sub-emission areas SEA. The transmission area TA may surround the sub-emission areas SEA.

In some embodiments, a plurality of portions of the transmission area TA may be arranged in the fourth direction DR4 and the fifth direction DR5 which are diagonal directions between the first direction DR1 and the second direction DR2. The portions of the transmission area TA may be arranged alternately with the sub-display pixels SDX in the first direction DR1 and the second direction DR2.

Due to the transmission area TA, the number of sub-emission areas SEA per unit area in the sub-display area SDA may be different from the number of main-emission areas MEA per unit area in the main display area MDA. In an embodiment, for example, the number of sub-emission areas SEA per unit area in the sub-display area SDA may be smaller than the number of main-emission areas MEA per unit area in the main display area MDA.

In addition, due to the transmission area TA, a ratio of the area of the sub-emission areas SEA to the area of the sub-display area SDA may be different from a ratio of the area of the main emission areas MEA to the area of the main display area MDA. In an embodiment, for example, the ratio of the area of the sub-emission areas SEA to the area of the sub-display area SDA may be smaller than the ratio of the area of the main emission areas MEA to the area of the main display area MDA.

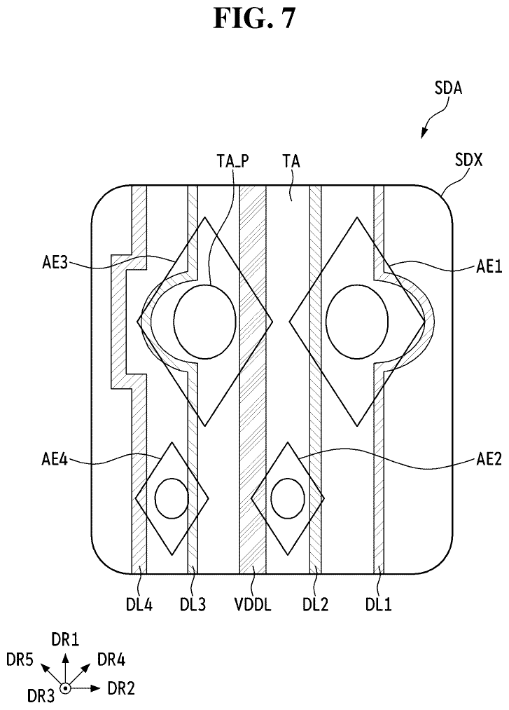

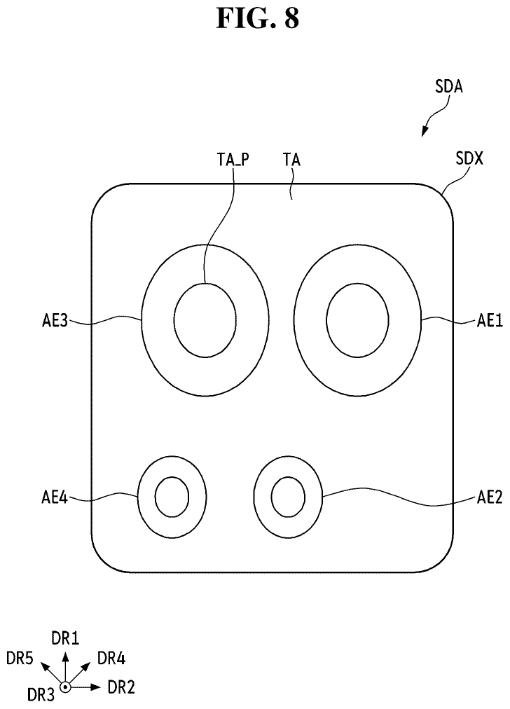

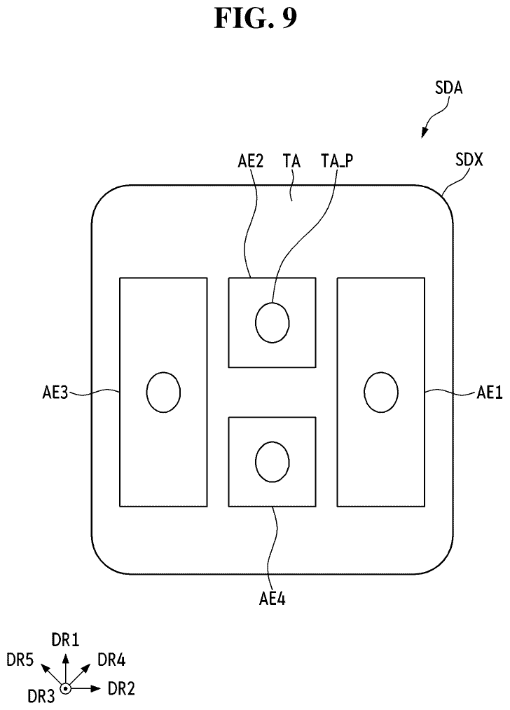

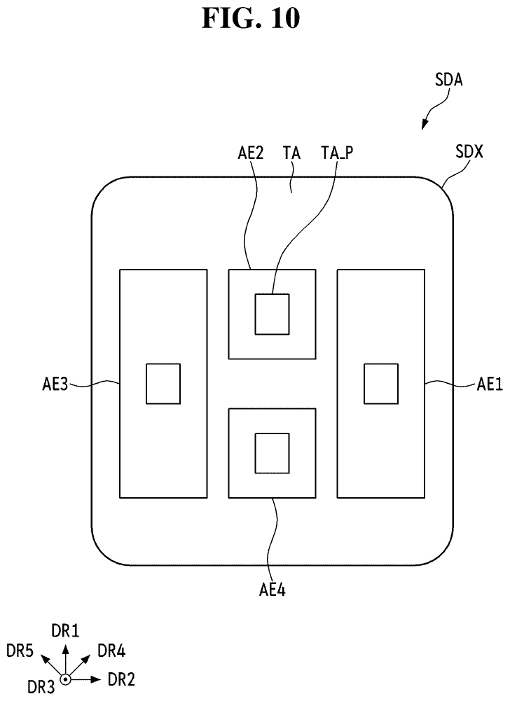

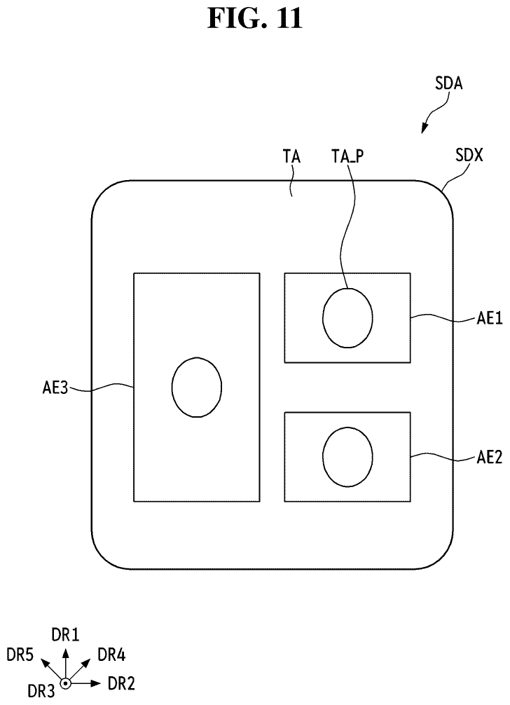

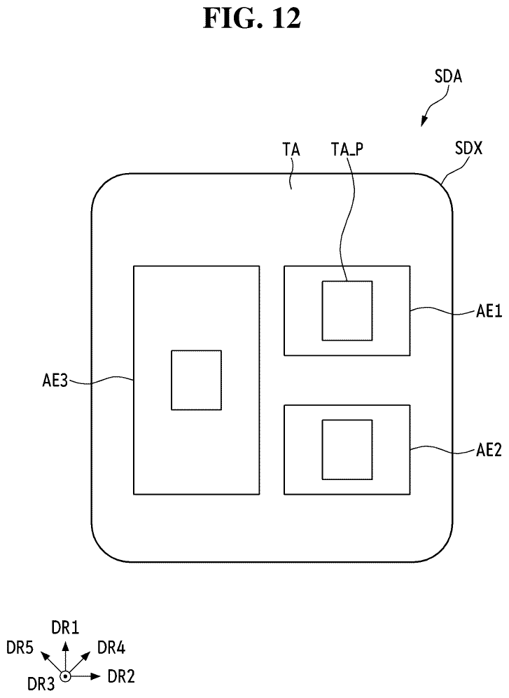

FIG. 7 is a plan view of an example of a sub-display pixel SDX according to an embodiment. FIG. 8 is a plan view of another example of the sub-display pixel SDX according to an embodiment. FIG. 9 is a plan view of another example of the sub-display pixel SDX according to an embodiment. FIG. 10 is a plan view of another example of the sub-display pixel SDX according to an embodiment. FIG. 11 is a plan view of another example of the sub-display pixel SDX according to an embodiment. FIG. 12 is a plan view of another example of the sub-display pixel SDX according to an embodiment.

FIGS. 7 through 12 illustrate the arrangement of pixel electrodes AE1, AE2, AE3 and AE4 of the sub-display pixel SDX in various embodiments.

Referring to FIGS. 7 through 12 in addition to FIGS. 3 through 6, the sub-display area SDA may include a plurality of sub-display pixels SDX, which include a plurality of sub-emission areas SEA, and a transmission area TA.

A sub-display pixel SDX may include a plurality of pixel electrodes AE1, AE2, AE3 and AE4. The pixel electrodes AE1, AE2, AE3 and AE4 may be anodes of light emitting elements ED (see FIG. 13) which emit light of different colors. In an embodiment, for example, a first pixel electrode AE1 may be an anode of a light emitting element, which emits light of a first color, and may be located in a first emission area. A second pixel electrode AE2 may be an anode of a light emitting element, which emits light of a second color, and may be located in a second emission area. A third pixel electrode AE3 may be an anode of a light emitting element, which emits light of a third color, and may be located in a third emission area. A fourth pixel electrode AE4 may be an anode of a light emitting element, which emits light of the second color, and may be located in a fourth emission area.

The first emission area may include a first main emission area located in the main display area MDA and a first sub-emission area located in the sub-display area SDA. The second emission area may include a second main emission area located in the main display area MDA and a second sub-emission area located in the sub-display area SDA. The third emission area may include a third main emission area located in the main display area MDA and a third sub-emission area located in the sub-display area SDA. The fourth emission area may include a fourth main emission area located in the main display area MDA and a fourth sub-emission area located in the sub-display area SDA. The first through fourth main emission areas may be included in the main emission areas MEA, and the first through fourth sub-emission areas may be included in the sub-emission areas SEA.

In an embodiment, the first emission area may emit first light, which is red light, the second emission area and the fourth emission area may emit second light, which is green light, and the third emission area may emit third light, which is blue light. However, the present disclosure is not limited to this example. A plurality of emission areas may be respectively defined by openings formed in a pixel defining layer PDL (see FIG. 13) of the light emitting element layer EML which will be described later.

The number, planar shape, and planar arrangement of the pixel electrodes AE1, AE2, AE3 and AE4 included in a sub-display pixel SDX can be variously changed or modified.

In some embodiments, as illustrated in FIGS. 7 through 10, one sub-display pixel SDX may include four pixel electrodes AE1, AE2, AE3 and AE4. In an embodiment, as illustrated in FIGS. 11 and 12, one sub-display pixel SDX may include three pixel electrodes AE1, AE2 and AE3. However, the number of pixel electrodes AE1, AE2, AE3 and AE4 included in one sub-display pixel SDX is not limited to these examples and can be variously changed or modified.

In some embodiments, as illustrated in FIG. 7, the planar shape of the pixel electrodes AE1, AE2, AE3 and AE4 may be a rhombus shape. In an embodiment, as illustrated in FIG. 8, the planar shape of the pixel electrodes AE1, AE2, AE3 and AE4 may be an elliptical shape. In an embodiment, as illustrated in FIGS. 9 through 12, the planar shape of the pixel electrodes AE1, AE2, AE3 and AE4 may be a quadrangular shape. However, the planar shape of the pixel electrodes AE1, AE2, AE3 and AE4 included in a sub-display pixel SDX is not limited to these examples and can be variously changed.

In some embodiments, as illustrated in FIGS. 7 and 8, the pixel electrodes AE1, AE2, AE3 and AE4 may be staggered with each other in the first direction DR1 and the second direction DR2. In an embodiment, for example, the first pixel electrode AE1 may be located side by side with the fourth pixel electrode AE4 in the fourth direction DR4, and the second pixel electrode AE2 may be located side by side with the third pixel electrode AE3 in the fifth direction DR5. In an embodiment, as illustrated in FIGS. 9 and 10, the second pixel electrode AE2 and the fourth pixel electrode AE4 may neighbor each other in the first direction DR1 and may neighbor the first pixel electrode AE1 and the third pixel electrode AE3 in the second direction DR2. In an embodiment, as illustrated in FIGS. 11 and 12, the first pixel electrode AE1 and the second pixel electrode AE2 may neighbor each other in the first direction DR1 and may neighbor the third pixel electrode AE3 in the second direction DR2. However, the planar arrangement of the pixel electrodes AE1, AE2, AE3 and AE4 included in a sub-display pixel SDX is not limited to these examples and can be variously changed or modified.

Although a sub-display pixel SDX is described as an example in the drawings, the number, planar shape and planar arrangement of the pixel electrodes AE1, AE2, AE3 and AE4 may be equally applied to a main display pixel MDX. Alternatively, the number, planar shape and planar arrangement of pixel electrodes AE1, AE2, AE3 and AE4 of the main display pixel MDX may be different from the number, planar shape and planar arrangement of the pixel electrodes AE1, AE2, AE3 and AE4 of the sub-display pixel SDX.

In the display device 10 according to an embodiment, a sub-display pixel SDX of the sub-display area SDA may include pixel transmission areas TA_P (e.g., sub-transmission portions) that penetrate (or is defined through) the pixel electrodes AE1, AE2, AE3 and AE4 of the sub-display area SDA.

Each of the pixel transmission areas TA_P is an area that passes light incident on the display panel 100. In an embodiment, for example, each of the pixel transmission areas TA_P may be an area where conductive patterns of the circuit layer TFTL, element patterns of the light emitting element layer EML, and the light blocking layer BM (see FIG. 13) and the color filters CF (see FIG. 13) of the color filter layer CFL are not located.

The pixel transmission areas TA_P may be located or defined on the pixel electrodes AE1, AE2, AE3 and AE4 of the sub-display area SDA. The pixel transmission areas TA_P may be located or defined on the sub-emission areas SEA. The number, planar shape and planar arrangement of the pixel transmission areas TA_P can be variously changed or modified.

In some embodiments, the number of pixel transmission areas TA_P included in one sub-display pixel SDX may be equal to the number of pixel electrodes AE1, AE2, AE3 and AE4. In an embodiment, for example, as illustrated in FIGS. 7 through 10, when four pixel electrodes AE1, AE2, AE3 and AE4 are included in one sub-display pixel SDX, the sub-display pixel SDX may include four pixel transmission areas TA_P. In an embodiment, as illustrated in FIGS. 11 and 12, when three pixel electrodes AE1, AE2 and AE3 are included in one sub-display pixel SDX, the sub-display pixel SDX may include three pixel transmission areas TA_P. However, the number of pixel transmission areas TA_P included in one sub-display pixel SDX is not limited to these examples and can be variously changed according to the number of pixel electrodes AE1, AE2, AE3 and AE4.

In some embodiments, the number of pixel transmission areas TA_P included in one sub-display pixel SDX may be different from the number of pixel electrodes AE1, AE2, AE3 and AE4. In an embodiment, for example, the number of pixel transmission areas TA_P included in one sub-display pixel SDX may be less than the number of pixel electrodes AE1, AE2, AE3 and AE4. In such an embodiment, some of the pixel electrodes AE1, AE2, AE3 and AE4 may not be penetrated by a pixel transmission area TA_P.

In some embodiments, as illustrated in FIGS. 7 through 9 and 11, the planar shape of the pixel transmission areas TA_P may be an elliptical shape. In an embodiment, as illustrated in FIGS. 10 and 12, the planar shape of the pixel transmission areas TA_P may be a quadrangular shape. However, the planar shape of the pixel transmission areas TA_P included in a sub-display pixel SDX is not limited to these examples and can be variously changed.

The planar arrangement of the pixel transmission areas TA_P in a sub-display pixel SDX may correspond to the planar arrangement of the pixel electrodes AE1, AE2, AE3 and AE4. The pixel transmission areas TA_P may be surrounded by the pixel electrodes AE1, AE2, AE3 and AE4 in plan view. In an embodiment, for example, each of the pixel transmission areas TA_P may be located approximately at a center of a pixel electrode AE1, AE2, AE3 or AE4 in plan view. However, the present disclosure is not limited to this example, and each of the pixel transmission areas TA_P may also be located close to one edge of the pixel electrode AE1, AE2, AE3 or AE4 in plan view.

In an embodiment, the pixel transmission areas TA_P may be directly connected to the transmission area TA without being enclosed by the pixel electrodes AE1, AE2, AE3 and AE4 in plan view. In an embodiment, for example, although the pixel transmission areas TA_P are shown as being surrounded by the pixel electrodes AE1, AE2, AE3 and AE4 and spaced apart from the transmission area TA in plan view, the present disclosure is not limited to this case. That is, each of the pixel transmission areas TA_P and the transmission area TA may be directly connected to each other in plan view by penetrating one side of a pixel electrode AE1, AE2, AE3 or AE4.

Since the display device 10 according to embodiments includes the pixel transmission areas TA_P (e.g., the sub-transmission portions), which penetrate or is defined (to extend) through the pixel electrodes AE1, AE2, AE3 and AE4, in addition to the transmission area TA (e.g., the main transmission portion) of the sub-display area SDA, the transmittance of the sub-display area SDA can be improved, and the uniformity of light incident on the sub-display area SDA can be improved.

In an embodiment, as shown in FIG. 7, lines of the thin-film transistor layer (e.g., the circuit layer) TFTL, which pass under the pixel electrodes AE1, AE2, AE3 and AE4 in the sub-display area SDA, may bypass the pixel transmission areas TA_P without overlapping the pixel transmission areas TA_P.

In an embodiment, for example, first, second, third and fourth data lines DL1, DL2, DL3 and DL4, which are connected to pixel circuits of the sub-emission areas SEA, and a driving voltage line VDDL, which supplies a voltage to each of the pixel electrodes AE1, AE2, AE3 and AE4, may at least partially overlap the pixel electrodes AE1, AE2, AE3 and AE4 in the third direction DR3. If the first data line DL1 and the third data line DL3 extend straight along the first direction DR1, they may overlap the pixel transmission areas TA_P, thereby reducing the transmittance of the pixel transmission areas TA_P. Therefore, the first data line DL1 and the third data line DL3 may bypass the pixel transmission areas TA_P not to overlap the pixel transmission areas TA_P.

Although the first, second, third and fourth data lines DL1, DL2, DL3 and DL4 and the driving voltage line VDDL extending in the first direction DR1 in the drawings are described as an example, the present disclosure is not limited to this example. The lines described with reference to FIG. 4 (e.g., the data lines DL and the driving voltage lines VDDL extending in the first direction DR1 and the gate lines GL and the emission control lines ECL extending in the second direction DR2) may also bypass the pixel transmission areas TA_P not to overlap the pixel transmission areas TA_P.

FIG. 13 is a cross-sectional view of the sub-display area SDA of the display device 10 taken along line X2-X2′ of FIG. 6.

Referring to FIG. 13 in addition to FIG. 6, in an embodiment, the display panel 100 of the display device 10 may include the substrate SUB, the thin-film transistor layer TFTL, the light emitting element layer EML, the encapsulation layer TFEL, the touch sensing layer TSU, and the color filter layer CFL.

The substrate SUB may be a base substrate or a base member. The substrate SUB may be a flexible substrate that can be bent, folded, rolled, etc. In an embodiment, for example, the substrate SUB may include polymer resin such as polyimide (PI), but the present disclosure is not limited to this example. In another embodiment, for example, the substrate SUB may include a glass material or a metal material.

The thin-film transistor layer TFTL may include a thin-film transistor TFT. The thin-film transistor TFT may constitute a pixel circuit of each of a plurality of pixels. In an embodiment, for example, the thin-film transistor TFT may be a driving transistor or a switching transistor of the pixel circuit. The thin-film transistor TFT may include a channel portion ACT, a source electrode SE, a drain electrode DE, and a gate electrode GE.

The channel portion ACT may overlap the gate electrode GE in the third direction DR3 (e.g., in the thickness direction). In portions of the channel portion ACT, the material of a semiconductor layer may be made conductive to form the source electrode SE and the drain electrode DE on opposite sides of the channel portion ACT, respectively.

The thin-film transistor layer TFTL may include a first buffer layer BF1, a bottom conductive layer, a second buffer layer BF2, a semiconductor layer, a gate insulating layer GI, a first gate conductive layer, a first interlayer insulating layer ILD1, a second gate conductive layer, a second interlayer insulating layer ILD2, a first source-drain conductive layer, a first passivation layer PAS1, a second source-drain conductive layer, and a second passivation layer PAS2.

The first buffer layer BF1 may be located on the substrate SUB. The first buffer layer BF1 may include an inorganic layer that can prevent penetration of air or moisture. In an embodiment, for example, the first buffer layer BF1 may include a plurality of inorganic layers stacked alternately.

The bottom conductive layer may be located on the first buffer layer BF1. In an embodiment, for example, the bottom conductive layer may be a single layer or a multilayer including at least one selected from molybdenum (Mo), aluminum (Al), chromium (Cr), gold (Au), titanium (Ti), nickel (Ni), neodymium (Nd), copper (Cu), and alloys thereof. The bottom conductive layer may include a bottom conductive pattern BML. The bottom conductive pattern BML may effectively prevent electromagnetic waves from being introduced from the outside into the thin-film transistor TFT.

The second buffer layer BF2 may be located on the bottom conductive layer. The second buffer layer BF2 may cover the first buffer layer BF1 and the bottom conductive layer. The second buffer layer BF2 may include an inorganic layer that can prevent penetration of air or moisture. In an embodiment, for example, the second buffer layer BF2 may include a plurality of inorganic layers stacked alternately.

The semiconductor layer may be located on the second buffer layer BF2. The semiconductor layer may include polycrystalline silicon, monocrystalline silicon, low-temperature polycrystalline silicon, amorphous silicon, or an oxide semiconductor material. The semiconductor layer may include the channel portion ACT, the source electrode SE, and the drain electrode DE of the thin-film transistor TFT.

The gate insulating layer GI may be located on the semiconductor layer. The gate insulating layer GI may cover the semiconductor layer and the second buffer layer BF2. The gate insulating layer GI may insulate the first semiconductor layer from the first gate conductive layer. The gate insulating layer GI may be provided with a contact hole through which a first connection electrode CNE1 passes.

The gate insulating layer GI may be a single layer or a multilayer in which one or more inorganic layers selected from, for example, a silicon nitride layer, a silicon oxynitride layer, a silicon oxide layer, a titanium oxide layer, and an aluminum oxide layer are alternately stacked.

The first gate conductive layer may be located on the gate insulating layer GI. The first gate conductive layer may be a single layer or a multilayer including at least one selected from molybdenum (Mo), aluminum (Al), chromium (Cr), gold (Au), titanium (Ti), nickel (Ni), neodymium (Nd), copper (Cu), and alloys thereof. The first gate conductive layer may include the gate electrode GE of the thin-film transistor TFT.

The first interlayer insulating layer ILD1 may be located on the first gate conductive layer. The first interlayer insulating layer ILD1 may cover the first gate conductive layer and the gate insulating layer GI. The first interlayer insulating layer ILD1 may insulate the first gate conductive layer from the second gate conductive layer. The first interlayer insulating layer ILD1 may be provided with a contact hole through which the first connection electrode CNE1 passes. The contact hole of the first interlayer insulating layer ILD1 may be connected to the contact hole of the gate insulating layer GI and a contact hole of the second interlayer insulating layer ILD2.

The first interlayer insulating layer ILD1 may be a single layer or a multilayer in which one or more inorganic layers selected from, for example, a silicon nitride layer, a silicon oxynitride layer, a silicon oxide layer, a titanium oxide layer, and an aluminum oxide layer are alternately stacked.

The second gate conductive layer may be located on the first interlayer insulating layer ILD1. The second gate conductive layer may be a single layer or a multilayer including at least one selected from molybdenum (Mo), aluminum (Al), chromium (Cr), gold (Au), titanium (Ti), nickel (Ni), neodymium (Nd), copper (Cu), and alloys thereof. The second gate conductive layer may include a capacitor electrode CAE. The capacitor electrode CAE may overlap the gate electrode GE in the thickness direction. The capacitor electrode CAE and the gate electrode GE may form capacitance.

The second interlayer insulating layer ILD2 may be located on the second gate conductive layer. The second interlayer insulating layer ILD2 may cover the second gate conductive layer and the first interlayer insulating layer ILD1. The second interlayer insulating layer ILD2 may insulate the second gate conductive layer from the first source-drain conductive layer. The second interlayer insulating layer ILD2 may be provided with a contact hole through which the first connection electrode CNE1 passes. The contact hole of the second interlayer insulating layer ILD2 may be connected to the contact hole of the first interlayer insulating layer ILD1.

The second interlayer insulating layer ILD2 may be a single layer or a multilayer in which one or more inorganic layers selected from, for example, a silicon nitride layer, a silicon oxynitride layer, a silicon oxide layer, a titanium oxide layer, and an aluminum oxide layer are alternately stacked.

The first source-drain conductive layer may be located on the second interlayer insulating layer ILD2. The first source-drain conductive layer may be a single layer or a multilayer including at least one selected from molybdenum (Mo), aluminum (Al), chromium (Cr), gold (Au), titanium (Ti), nickel (Ni), neodymium (Nd), copper (Cu), and alloys thereof. The first source-drain conductive layer may include the first connection electrode CNE1.

The first connection electrode CNE1 may electrically connect the drain electrode DE of the thin-film transistor TFT and a second connection electrode CNE2. The first connection electrode CNE1 may be inserted into the contact hole formed or defined in the second interlayer insulating layer ILD2, the first interlayer insulating layer ILD1 and the gate insulating layer GI to contact the drain electrode DE of the thin-film transistor TFT.

The first passivation layer PAS1 may be located on the first source-drain conductive layer. The first passivation layer PAS1 may cover the first source-drain conductive layer and the second interlayer insulating layer ILD2. The first passivation layer PAS1 may protect the thin-film transistor TFT. The first passivation layer PAS1 may be provided with a contact hole through which the second connection electrode CNE2 passes.

The first passivation layer PAS1 may include an organic layer such as acryl resin, epoxy resin, phenolic resin, polyamide resin, or polyimide resin.

The second source-drain conductive layer may be located on the first passivation layer PAS1. The second source-drain conductive layer may be a single layer or a multilayer including at least one selected from molybdenum (Mo), aluminum (Al), chromium (Cr), gold (Au), titanium (Ti), nickel (Ni), neodymium (Nd), copper (Cu), and alloys thereof. The second source-drain conductive layer may include the second connection electrode CNE2.

The second connection electrode CNE2 may electrically connect the first connection electrode CNE1 and a pixel electrode AE of a light emitting element ED. The second connection electrode CNE2 may be inserted into the contact hole formed in the first passivation layer PAS1 to contact the first connection electrode CNE1.

The second passivation layer PAS2 may be located on the second source-drain conductive layer. The second passivation layer PAS2 may cover the second source-drain conductive layer and the first passivation layer PAS1. The second passivation layer PAS2 may include a contact hole through which the pixel electrode AE of the light emitting element ED passes.

The second passivation layer PAS2 may include an organic layer such as acryl resin, epoxy resin, phenolic resin, polyamide resin, or polyimide resin.

The light emitting element layer EML may be located on the thin-film transistor layer TFTL. The light emitting element layer EML may include the light emitting element ED and a pixel defining layer PDL. The light emitting element ED may include the pixel electrode AE, a light emitting layer EL, and a common electrode CE.

The pixel electrode AE may be located on the second passivation layer PAS2. The pixel electrode AE may overlap an opening of the pixel defining layer PDL. The pixel electrode AE may be electrically connected to the drain electrode DE of the thin-film transistor TFT through the first and second connection electrodes CNE1 and CNE2.

The pixel electrode AE may be formed as a single layer of molybdenum (Mo), titanium (Ti), copper (Cu) or aluminum (Al) or, in order to increase reflectivity, may be formed as a stacked structure (Ti/Al/Ti) of aluminum and titanium, a stacked structure (ITO/Al/ITO) of aluminum and indium tin oxide, an APC alloy, or a stacked structure (ITO/APC/ITO) of an APC alloy and indium tin oxide. The APC alloy is an alloy of silver (Ag), palladium (Pd), and copper (Cu).

The pixel defining layer PDL may be located on the second passivation layer PAS2 and a portion of the pixel electrode AE. The pixel defining layer PDL may include a plurality of openings. Each of the openings of the pixel defining layer PDL may expose a portion of the pixel electrode AE. As described above, the openings of the pixel defining layer PDL may define the main emission areas MEA and the sub-emission areas SEA, respectively. The pixel defining layer PDL may separate and insulate the respective pixel electrodes AE of a plurality of light emitting elements ED.

The pixel defining layer PDL may include a light absorbing material to prevent light reflection. In an embodiment, for example, the pixel defining layer PDL may include a polyimide (PI)-based binder and a pigment in which red, green and blue are mixed together. Alternatively, the pixel defining layer PDL may include a cardo-based binder resin and a mixture of a lactam black pigment and a blue pigment. Alternatively, the pixel defining layer PDL may include carbon black.

In some embodiments, the light emitting layer EL may be an organic light emitting layer including an organic material, but the present disclosure is not limited to this example. In an embodiment where the light emitting layer EL includes an organic material, it may include a hole transporting layer, an organic light emitting layer, and an electron transporting layer. When an anode voltage is applied to the pixel electrode AE through the thin-film transistor TFT and a cathode voltage is applied to the common electrode CE, holes and electrons move to the organic light emitting layer through the hole transporting layer and the electron transporting layer, respectively, and are combined with each other in the organic light emitting layer to emit light.

The common electrode CE may be located on the light emitting layer EL. In an embodiment, for example, the common electrode CE may be implemented as an electrode common to all pixels without being separated for each pixel. The common electrode CE may be located on the light emitting layer EL on the pixel electrode AE and may be located on the pixel defining layer PDL in an area excluding the pixel electrode AE.

The common electrode CE may receive a common voltage or a low potential voltage. When the pixel electrode AE receives a voltage corresponding to a data voltage and the common electrode CE receives a low potential voltage, a potential difference is formed between the pixel electrode AE and the common electrode CE. Accordingly, the light emitting layer EL may emit light.

The encapsulation layer TFEL may be located on the common electrode CE and may cover the light emitting elements ED. The encapsulation layer TFEL may include at least one inorganic layer to prevent oxygen or moisture from penetrating into the light emitting element layer EML. The encapsulation layer TFEL may include at least one organic layer to protect the light emitting element layer EML from foreign substances such as dust.

In an embodiment, the encapsulation layer TFEL may include a first encapsulation layer TFE1, a second encapsulation layer TFE2, and a third encapsulation layer TFE3. The first encapsulation layer TFE1 and the third encapsulation layer TFE3 may be inorganic encapsulation layers, and the second encapsulation layer TFE2 located between the first encapsulation layer TFE1 and the third encapsulation layer TFE3 may be an organic encapsulation layer.

Each of the first encapsulation layer TFE1 and the third encapsulation layer TFE3 may include one or more inorganic insulating materials. The inorganic insulating materials may include aluminum oxide, titanium oxide, tantalum oxide, hafnium oxide, zinc oxide, silicon oxide, silicon nitride, and/or silicon oxynitride.

The second encapsulation layer TFE2 may include a polymer-based material. Examples of the polymer-based material may include acrylic resin, epoxy resin, polyimide, and polyethylene. In an embodiment, for example, the second encapsulation layer TFE2 may include acrylic resin such as polymethyl methacrylate or polyacrylic acid. The second encapsulation layer TFE2 may be formed by curing a monomer or applying a polymer.

The touch sensing layer TSU may be located on the encapsulation layer TFEL. The touch sensing layer TSU may include a first touch insulating layer SIL1, a second touch insulating layer SIL2, touch electrodes TL, and a third touch insulating layer SIL3.

The first touch insulating layer SIL1 may be located on the encapsulation layer TFEL. The first touch insulating layer SIL1 may have insulating and optical functions. The first touch insulating layer SIL1 may include at least one inorganic layer. Optionally, the first touch insulating layer SIL1 may be omitted.

The second touch insulating layer SIL2 may cover the first touch insulating layer SIL1. Although not illustrated in the drawing, a touch electrode TL of another layer may be further located on the first touch insulating layer SIL1, and the second touch insulating layer SIL2 may cover the touch electrode TL. The second touch insulating layer SIL2 may have insulating and optical functions. In an embodiment, for example, the second touch insulating layer SIL2 may be an inorganic layer including at least one selected from a silicon nitride layer, a silicon oxynitride layer, a silicon oxide layer, a titanium oxide layer, and an aluminum oxide layer.

Some of the touch electrodes TL may be located on the second touch insulating layer SIL2. Each of the touch electrodes TL may not overlap the pixel electrode AE. Each of the touch electrodes TL may be formed as a single layer of molybdenum (Mo), titanium (Ti), copper (Cu), aluminum (Al) or indium tin oxide (ITO) or may be formed as a stacked structure (Ti/Al/Ti) of aluminum and titanium, a stacked structure (ITO/Al/ITO) of aluminum and indium tin oxide, an APC alloy, or a stacked structure (ITO/APC/ITO) of an APC alloy and indium tin oxide.

The touch electrodes TL of the touch sensing layer TSU may have a certain line width and overlap a light blocking layer BM. The light blocking layer BM may have a width sufficient to completely cover the touch electrodes TL. In some embodiments, a center of each touch electrode TL may be substantially aligned with a center of the light blocking layer BM. A distance from one side of the touch electrode TL to one side of the light blocking layer BM may be substantially the same as a distance from the other side of the touch electrode TL to the other side of the light blocking layer BM.

The third touch insulating layer SIL3 may cover the touch electrodes TL and the second touch insulating layer SIL2. The third touch insulating layer SIL3 may have insulating and optical functions. The third touch insulating layer SIL3 may include a material exemplified in the second touch insulating layer SIL2.

The color filter layer CFL may include the light blocking layer BM, a color filter CF, and an overcoat layer OC.

The light blocking layer BM may be located on the third touch insulating layer SIL3 of the touch sensing layer TSU. The light blocking layer BM may overlap conductive lines of the touch electrodes TL. The light blocking layer BM may overlap the pixel defining layer PDL in the third direction DR3.

The light blocking layer BM may include openings which overlap the main emission areas MEA and the sub-emission areas SEA. The openings of the light blocking layer BM may be wider than the main emission areas MEA and the sub-emission areas SEA. Accordingly, light emitted from the light emitting elements ED may be visible to a user not only from the front of the display device 10 but also from the side.

The light blocking layer BM may include a light absorbing material. In an embodiment, for example, the light blocking layer BM may include an inorganic black pigment or an organic black pigment. The inorganic black pigment may be carbon black, and the organic black pigment may include at least one of lactam black, perylene black, and aniline black, but the present disclosure is not limited to this example.

The color filter CF may be located on the light blocking layer BM. The color filter CF may overlap each of the openings of the light blocking layer BM. The color filter CF may overlap each of the main emission areas MEA and the sub-emission areas SEA.

The overcoat layer OC may be located on the light blocking layer BM and the color filter CF. The overcoat layer OC may be located over the entire display area DA to flatten an upper surface of the display panel 100. The overcoat layer OC may be a colorless, light-transmitting layer that does not have a color in a visible light band. In an embodiment, for example, the overcoat layer OC may include a colorless, light-transmitting organic material such as acrylic resin.

The transmission area TA may be an area where a conductive layer of the circuit layer TFTL, a light emitting element of the light emitting element layer EML, a conductive layer of the touch sensing layer TSU, and the light blocking layer BM and the color filters CF of the color filter layer CFL are not located to transmit light.

The substrate SUB may be located in the transmission area TA. In the transmission area TA, at least one of the first buffer layer BF1, the second buffer layer BF2, the gate insulating layer GI, the first interlayer insulating layer ILD1, the second interlayer insulating layer ILD2, the first passivation layer PAS1 and the second passivation layer PAS2 of the thin-film transistor layer TFTL, the pixel defining layer PDL of the light emitting element layer EML, the encapsulation layer TFEL, and the first touch insulating layer SIL1, the second touch insulating layer SIL2 and the third touch insulating layer SIL3 of the touch sensing layer TSU may be further located on the substrate SUB.

In an embodiment, for example, as illustrated in the drawing, the first buffer layer BF1, the second buffer layer BF2, the gate insulating layer GI, the first interlayer insulating layer ILD1, the second interlayer insulating layer ILD2, the first passivation layer PAS1 and the second passivation layer PAS2 of the thin-film transistor layer TFTL, the pixel defining layer PDL of the light emitting element layer EML, the encapsulation layer TFEL, and the first touch insulating layer SIL1, the second touch insulating layer SIL2 and the third touch insulating layer SIL3 of the touch sensing layer TSU may all be located in the transmission area TA.

In another embodiment, for example, the first touch insulating layer SIL1, the second touch insulating layer SIL2 and the third touch insulating layer SIL3 of the touch sensing layer TSU may end before the transmission area TA without extending to the transmission area TA, and the overcoat layer OC may be located in a part where the first touch insulating layer SIL1, the second touch insulating layer SIL2, and the third touch insulating layer SIL3 are not located.

In another embodiment, for example, when transmission holes TH1 and TH2, which will be described later, are located in the entire transmission area TA, only the first passivation layer PAS1 of the thin-film transistor layer TFTL, the encapsulation layer TFE, and the first touch insulating layer SIL1, the second touch insulating layer SIL2 and the third touch insulating layer SIL3 of the touch sensing layer TSU may be located in the transmission area TA. That is, only a part where the transmission holes TH1 and TH2 are located may be defined as the transmission area TA.

However, the present disclosure is not limited to the above examples, and the type of layers included in the transmission area TA may vary depending on the type of layers through which the transmission holes TH1 and TH2 penetrate.

The transmission area TA may include or be defined by the transmission holes TH1 and TH2. In some embodiments, the transmission holes TH1 and TH2 may include a first transmission hole TH1 located under the first passivation layer PAS1 and a second transmission hole TH2 located on the first passivation layer PAS2.

The first transmission hole TH1 may be a hole that penetrates or is defined through the first buffer layer BF1, the second buffer layer BF2, the gate insulating layer GI, the first interlayer insulating layer ILD1 and the second interlayer insulating layer ILD2 to allow the substrate SUB and the first passivation layer PAS1 to directly contact each other. The first transmission hole TH1 may be filled with the first passivation layer PAS1.

The second transmission hole TH2 may be a hole that penetrates or is defined through the second passivation layer PAS2 and the pixel defining layer PDL to allow the first encapsulation layer TFE1 and the first passivation layer PAS1 to directly contact each other. The second transmission hole TH2 may be filled with the encapsulation layer TFEL. In an embodiment, for example, the second transmission hole TH2 may be filled with the first encapsulation layer TFE1 and the second encapsulation layer TFE2.

The present disclosure is not limited to the illustration in the drawing, and a layer that divides the first transmission hole TH1 and the second transmission hole TH2 may also be the second passivation layer PAS2. In an embodiment, the first transmission hole TH1 may also penetrate the first passivation layer PAS1, and the second passivation layer PAS2 may fill the first transmission hole TH1.

A pixel transmission area TA_P may be an area where a conductive layer of the circuit layer TFTL, a light emitting element of the light emitting element layer EML, a conductive layer of the touch sensing layer TSU, and the light blocking layer BM and the color filters CF of the color filter layer CFL are not located to transmit light. The pixel transmission area TA_P may overlap a sub-emission area SEA.

The pixel transmission area TA_P may penetrate or be defined through the bottom conductive pattern BML, the pixel electrode AE, the light emitting layer EL, the common electrode CE, and the color filter CF. In an embodiment, for example, the bottom conductive pattern BML may be provided with a first opening OP_B, the pixel electrode AE may be provided with a second opening OP_A, the light emitting layer EL may be provided with a third opening OP_E, the common electrode CE may be provided with a fourth opening OP_C, and the color filter CF may include a fifth opening OP_F to the pixel transmission area TA_P defined therethrough in the third direction DR3.

In some embodiments, the first opening OP_B of the bottom conductive pattern BML, the second opening OP_A of the pixel electrode AE, and the fifth opening OP_F of the color filter CF may be formed by a patterning process. In such embodiments, when the bottom conductive pattern BML, the pixel electrode AE, and the color filter CF are formed, the first opening OP_B, the second opening OP_A, and the fifth opening OP_F may be formed from the beginning. In an embodiment, the third opening OP_E of the light emitting layer EL and the fourth opening OP_C of the common electrode CE may be formed by a laser lift-off method. In such an embodiment, after the light emitting layer EL and the common electrode CE are formed, the third opening OP_E and the fourth opening OP_C may be formed through a separate laser removal process.

In an embodiment, the second opening OP_A of the pixel electrode AE may be formed together with the third opening OP_E of the light emitting layer EL and the fourth opening OP_C of the common electrode CE by a laser lift-off method.

Since the display device 10 according to an embodiment includes the pixel transmission area TA_P (e.g., a sub-transmission portion), which penetrates is defined through the pixel electrode AE, in addition to the transmission area TA (e.g., the main transmission portion) of the sub-display area SDA, the transmittance of the sub-display area SDA can be improved, and the uniformity of light incident on the sub-display area SDA can be improved.

Hereinafter, other embodiments of the display device 10 according to an embodiment will be described. In the following description of other embodiments, the same elements as those of the embodiments described above are labeled with the same reference characters, and any repetitive detailed description thereof will be omitted or simplified, and differences will be mainly described.

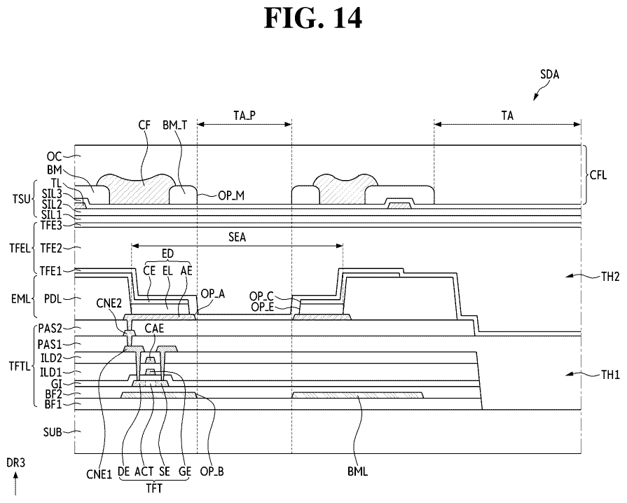

FIG. 14 is a cross-sectional view of a sub-display area of a display device 10 according to an embodiment.

the embodiment of display device 10 shown in FIG. 14 is substantially the same as the display device 10 according to the embodiment described with reference to FIG. 13, etc. except that a light blocking layer BM includes a transmission portion light-blocking layer BM_T and a pixel transmission hole OP_M.

More specifically, the light blocking layer BM may include the transmission portion light-blocking layer BM_T and the pixel transmission hole OP_M overlapping a pixel transmission area TA_P.

The transmission portion light-blocking layer BM_T may overlap a pixel electrode AE in the third direction DR3. The transmission portion light-blocking layer BM_T may be located adjacent to the pixel transmission area TA_P. The transmission portion light-blocking layer BM_T may surround the pixel transmission area TA_P in plan view. While portions of the light blocking layer BM excluding the transmission portion light-blocking layer BM_T overlap a pixel defining layer PDL, the transmission portion light-blocking layer BM_T may overlap a sub-emission area SEA, the pixel electrode AE, and a light emitting layer EL.

The pixel transmission hole OP_M may overlap the pixel transmission area TA_P in the third direction DR3. The pixel transmission hole OP_M may overlap a first opening OP_B of a bottom conductive pattern BML, may overlap a second opening OP_A of the pixel electrode AE, may overlap a third opening OP_E of the light emitting layer EL, and may overlap a fourth opening OP_C of a common electrode CE.

Color filters CF may not overlap the pixel transmission hole OP_M. The color filters CF may be located outside the transmission portion light-blocking layer BM_T not to overlap the pixel transmission hole OP_M. In an embodiment, for example, the color filters CF may be located between the transmission portion light-blocking layer BM_T and other portions of the light blocking layer BM. That is, the color filters CF may be located on opposite sides of the pixel transmission hole OP_M with the transmission portion light-blocking layer BM_T. The transmission portion light-blocking layer BM_T may be located between the color filters CF in a horizontal direction perpendicular to the third direction DR3.

Since the display device 10 according to an embodiment includes the transmission portion light-blocking layer BM_T and the pixel transmission hole OP_M, light leakage around the pixel transmission area TA_P can be effectively prevented. In an embodiment, for example, when light emitted from the light emitting layer EL, which surrounds the pixel transmission area TA_P, travels toward a color filter layer CFL, it can be effectively prevented from passing through the pixel transmission area TA_P.

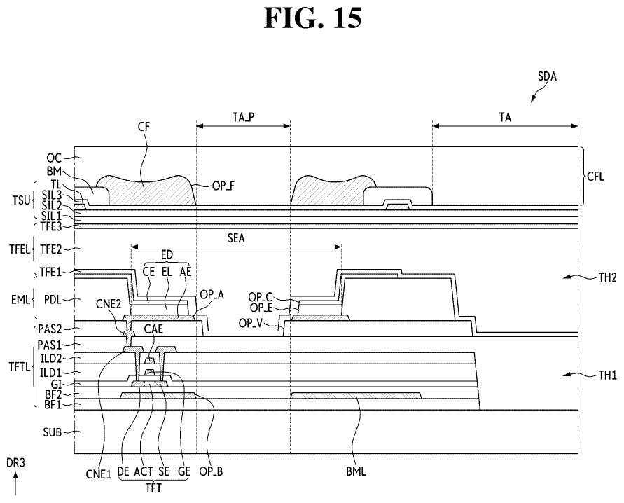

FIG. 15 is a cross-sectional view of a sub-display area of a display device 10 according to an embodiment.

The embodiment of the display device 10 shown in FIG. 15 is substantially the same as the display device 10 according to the embodiment described with reference to FIG. 13, etc. except that a sixth opening OP_V is defined in the second passivation layer PAS2.

In an embodiment, as shown in FIG. 15, the second passivation layer PAS2 may be provided with the sixth opening OP_V which overlaps a pixel transmission area TA_P and penetrates the second passivation layer PAS2 from an upper surface to a lower surface of the second passivation layer PAS2. The sixth opening OP_V may overlap a first opening OP_B of a bottom conductive pattern BML, a second opening OP_A of a pixel electrode AE, a third opening OP_E of a light emitting layer EL, a fourth opening OP_C of a common electrode CE, and a fifth opening OP_F of a color filter CF.

In such an embodiment, a first encapsulation layer TFE1 may directly cover not only side surfaces of the common electrode CE, the light emitting layer EL and the pixel electrode AE, but also side surfaces of the second passivation layer PAS2. The first encapsulation layer TFE1 may also directly cover an upper surface of a first passivation layer PAS1 where the second passivation layer PAS2 is not located.

A second encapsulation layer TFE2 may be located not only in the fourth opening OP_C of the common electrode CE, the third opening OP_E of the light emitting layer EL and the second opening OP_A of the pixel electrode AE, but also in the sixth opening OP_V of the second passivation layer PAS2.

In the drawing, an embodiment where the common electrode CE to the second passivation layer PAS2 are removed from the pixel transmission area TA_P is shown as an example. However, the present disclosure is not limited to this example. In an embodiment, for example, a first buffer layer BF1, a second buffer layer BF2, a gate insulating layer GI, a first interlayer insulating layer ILD1, and a second interlayer insulating layer ILD2 may all be removed, or at least one of them may be removed. The smaller the number of insulating layers located in the pixel transmission area TA_P, the higher the transmittance in the pixel transmission area TA_P.

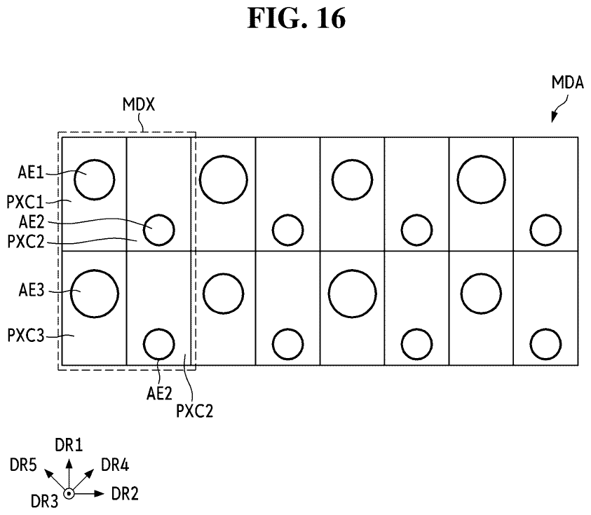

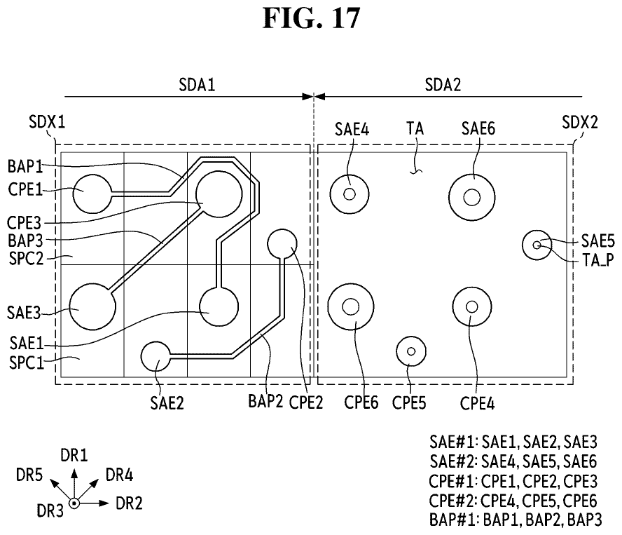

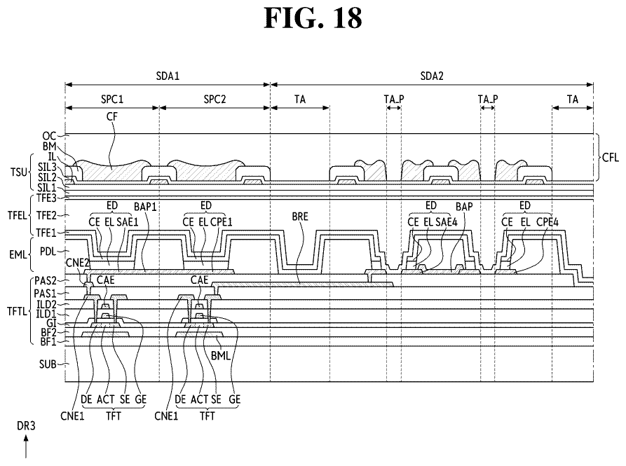

FIG. 16 is a plan view illustrating the arrangement of pixel electrodes in each main pixel of a display device 10 according to an embodiment. FIG. 17 is a plan view illustrating the arrangements of pixel electrodes in sub-pixels of the display device 10 according to the embodiment of FIG. 16. FIG. 18 is a cross-sectional view of a sub-display area SDA of the display device 10 according to the embodiment of FIG. 16.

The embodiments of the display device 10 shown in FIGS. 16 to 18 are substantially the same as the display devices 10 according to the embodiments described above with reference to FIGS. 13 through 15, etc. except that the sub-display area SDA includes a first sub-display area SDA1 and a second sub-display area SDA2.

In an embodiment, the display device 10 may include a plurality of pixel electrodes AE1, AE2 and AE3 located in a main display area MDA. The pixel electrodes AE1, AE2 and AE3 may be anodes of light emitting elements ED which emit light of different colors. In an embodiment, for example, a first pixel electrode AE1 may be an anode of a light emitting element, which emits light of a first color, and may be located in a first emission area. A second pixel electrode AE2 may be an anode of a light emitting element, which emits light of a second color, and may be located in a second emission area. A third pixel electrode AE3 may be an anode of a light emitting element, which emits light of a third color, and may be located in a third emission area. In an embodiment, the first emission area may emit first light, which is red light, the second emission area may emit second light, which is green light, and the third emission area may emit third light, which is blue light. However, the present disclosure is not limited to this example. A plurality of emission areas may be respectively defined by openings formed in a pixel defining layer PDL of a light emitting element layer EML which will be described later.

The pixel electrodes AE1, AE2 and AE3 may be arranged in a pentile™ type, for example, a diamond pentile™ type. In an embodiment, for example, the first pixel electrode AE1 and the third pixel electrode AE3 may be spaced apart from each other in the first direction DR1 and the second direction DR2 and may be alternately arranged. The second pixel electrode AE2 may be spaced apart from another adjacent second pixel electrode AE2 in the first direction DR1 and the second direction DR2 and may be spaced apart from an adjacent first pixel electrode AE1 and an adjacent third pixel electrode AE3 in diagonal directions.

A plurality of pixel circuits PXC1, PXC2 and PXC3 located in the main display area MDA may each correspond to one pixel electrode AE1, AE2 or AE3. In an embodiment, for example, a first pixel circuit PXC1 may correspond to one first pixel electrode AE1 and may be electrically connected to the first pixel electrode AE1. A second pixel circuit PXC2 may correspond to one second pixel electrode AE2 and may be electrically connected to the second pixel electrode AE2. A third pixel circuit PXC3 may correspond to one third pixel electrode AE3 and may be electrically connected to the third pixel electrode AE3. A main display pixel MDX including four pixel electrodes AE1, AE2 and AE3 may include four pixel circuits PXC1, PXC2 and PXC3.

Referring to FIG. 17, the display device 10 may include a plurality of sub-pixel electrodes SAE1 through SAE6, a plurality of copy pixel electrodes CPE1 through CPE6, and a plurality of bridge electrodes BAP1, BAP2 and BAP3 located in the sub-display area SDA. One sub-pixel electrode SAE1, SAE2, SAE3, SAE4, SAE5 or SAE6 and one copy pixel electrode CPE1, CPE2, CPE3, CPE4, CPE5 or CPE6 may each be an anode of a light emitting element ED. That is, light emitting elements ED may be located in the sub-display areas SDA1 and SDA2 to emit light, as in the main display area MDA.

In an embodiment of the display device 10, the configuration of sub-display pixels SDX1 and SDX2 of the sub-display area SDA may be different from the configuration of main display pixels MDX of the main display area MDA. In a first sub-display pixel SDX1, one sub-pixel electrode SAE1, SAE2 or SAE3 and one copy pixel electrode CPE1, CPE2 or CPE3 may be electrically connected to each other through a bridge electrode BAP1, BAP2 or BAP3. The sub-pixel electrode SAE1, SAE2 or SAE3 and the copy pixel electrode CPE1, CPE2 or CPE3 connected through the bridge electrode BAP1, BAP2 or BAP3 may be anodes of light emitting elements ED, respectively, which emit light of the same color.

In an embodiment, for example, a first sub-pixel electrode SAE1 and a first copy pixel electrode CPE1 located in the first sub-display area SDA1 may be electrically connected to each other through a first bridge electrode BAP1 and may respectively constitute light emitting elements which emit light of the first color. Emission areas where the first sub-pixel electrode SAE1 and the first copy pixel electrode CPE1 are located may emit light of the same color.

Similarly, a second sub-pixel electrode SAE2 and a second copy pixel electrode CPE2 located in the first sub-display area SDA1 may be electrically connected to each other through a second bridge electrode BAP2, and a third sub-pixel electrode SAE3 and a third copy pixel electrode CPE3 located in the first sub-display area SDA1 may be electrically connected to each other through a third bridge electrode BAP3. The second sub-pixel electrode SAE2 and the second copy pixel electrode CPE2 may respectively constitute light emitting elements which emit light of the second color, and the third sub-pixel electrode SAE3 and the third copy pixel electrode CPE3 may respectively constitute light emitting elements which emit light of the third color. Emission areas where the second sub-pixel electrode SAE2 and the second copy pixel electrode CPE2 are located may emit light of the same color, and emission areas where the third sub-pixel electrode SAE3 and the third copy pixel electrode CPE3 are located may emit light of a same color as each other.

According to an embodiment, sub-pixel electrodes SAE4, SAE5 and SAE6 and copy pixel electrodes CPE4, CPE5 and CPE6 located in the second sub-display area SDA2 may be electrically connected to each other through connection patterns BAP (see FIG. 18) located in the entire second sub-display area SDA2. In the second sub-display area SDA2, fourth, fifth and sixth sub-pixel electrodes SAE4, SAE5 and SAE6 and fourth, fifth and sixth copy pixel electrodes CPE4, CPE5 and CPE6 may be arranged in the same way as in the first sub-display area SDA1. However, a pair of a sub-pixel electrode SAE4, SAE5 or SAE6 and a copy pixel electrode CPE4, CPE5 or CPE6 may be connected through connection pattern located around them.

The fourth sub-pixel electrode SAE4 and the fourth copy pixel electrode CPE4 may constitute light emitting elements which emit light of the first color, the fifth sub-pixel electrode SAE5 and the fifth copy pixel electrode CPE5 may constitute light emitting elements which emit light of the second color, and the sixth sub-pixel electrode SAE6 and the sixth copy pixel electrode CPE6 may constitute light emitting elements which emit light of the third color.

The sub-pixel electrodes SAE1 through SAE6 and the copy pixel electrodes CPE1 through CPE6 may be arranged in a pentile™ type, for example, a diamond pentile™ type, like the pixel electrodes AE of the main display area MDA. In an embodiment, for example, the first sub-pixel electrode SAE1 and the third sub-pixel electrode SAE3 may be spaced apart from each other in the second direction DR2, and the third copy pixel electrode CPE3 and the first copy pixel electrode CPE1 may be spaced apart from the first sub-pixel electrode SAE1 and the third sub-pixel electrode SAE3 in the first direction DR1, respectively. The fourth sub-pixel electrode SAE4 and the sixth sub-pixel electrode SAE6 may be spaced apart from each other in the second direction DR2, and the sixth copy pixel electrode CPE6 and the fourth copy pixel electrode CPE4 may be spaced apart from the fourth sub-pixel electrode SAE4 and the sixth sub-pixel electrode SAE6 in the first direction DR1, respectively. The second sub-pixel electrode SAE2 and the second copy pixel electrode CPE2 may be spaced apart from each other in a diagonal direction (e.g., in the fourth direction DR4) with the first sub-pixel electrode SAE1. The first sub-pixel electrode SAE1 may be located between the second sub-pixel electrode SAE2 and the second copy pixel electrode CPE2. The fifth sub-pixel electrode SAE5 and the fifth copy pixel electrode CPE5 may be spaced apart from each other in a diagonal direction (e.g., in the fourth direction DR4) with the fourth copy pixel electrode CPE4. The fourth copy pixel electrode CPE4 may be located between the fifth sub-pixel electrode SAE5 and the fifth copy pixel electrode CPE5. Each of the bridge electrodes BAP1, BAP2 and BAP3 may connect a pair of a sub-pixel electrode SAE1, SAE2 or SAE3 and a copy pixel electrode CPE1, CPE2 or CPE3 to each other, but may bypass other sub-pixel electrodes SAE1 through SAE3, other copy pixel electrodes CPE1 through CPE3 and other bridge electrodes BAP1, BAP2 and BAP3 not to cross them.

The first sub-display pixel SDX1 located in the first sub-display area SDA1 may include six pixel electrodes, which include the first, second and third sub-pixel electrodes SAE1, SAE2 and SAE3 and the first, second and third copy pixel electrodes CPE1, CPE2 and CPE3, or six emission areas. A second sub-display pixel SDX2 located in the second sub-display area SDA2 may include six pixel electrodes, which include the fourth, fifth and sixth sub-pixel electrodes SAE4, SAE5 and SAE6 and the fourth, fifth and sixth copy pixel electrodes CPE4, CPE5 and CPE6, or six emission areas. The number of emission areas which emit light of a same color may be greater in the sub-display pixels SDX1 and SDX2 located in the sub-display area SDA than in the main display pixels MDX located in the main display area MDA. However, the number or density of emission areas per unit area may be greater in the main display pixels MDX than in the sub-display pixels SDX1 and SDX2. In addition, the number of light emitting elements which emit light of the first color and the number of light emitting elements which emit light of the third color are greater in the sub-display pixels SDX1 and SDX2 than in the main display pixels MDX. However, the number of light emitting elements which emit light of the second color may be the same in the sub-display pixels SDX1 and SDX2 and the main display pixels MDX. Accordingly, the resolution of the main display area MDA may be higher than that of the sub-display area SDA. The sub-display area SDA may have a lower resolution than the main display area MDA in consideration of the transmittance of light incident on an optical device 500 located under the sub-display area SDA.

In an embodiment, in the first sub-display area SDA1 of the sub-display area SDA, first sub-pixel circuits SPC1 electrically connected to the first sub-display pixel SDX1 and second sub-pixel circuits SPC2 electrically connected to the second sub-display pixel SDX2 may be located. On the other hand, in the second sub-display area SDA2, a pixel circuit may not be located, and the sub-pixel electrodes SAE4 through SAE6, the copy pixel electrodes CPE4 through CPE6, and bridge patterns BRE (see FIG. 18), which electrically connect the connection patterns BAP, the sub-pixel electrodes SAE4 through SAE6 and the copy pixel electrodes CPE4 through CPE6 to the second sub-pixel circuits SPC2, may be located.

The sub-pixel electrodes SAE1 through SAE6 and the copy pixel electrodes CPE1 through CPE6 located in the sub-display areas SDA1 and SDA2 of the display device 10 may be classified according to their positions and connection structures. In an embodiment, for example, the first, second and third sub-pixel electrodes SAE1, SAE2 and SAE3 located in the first sub-display area SDA1 may be connected to the first, second and third copy pixel electrodes CPE1, CPE2 and CPE3 through the first, second and third bridge electrodes BAP1, BAP2 and BAP3 which are located in the same layer as and are integrated with the first, second and third sub-pixel electrodes SAE1, SAE2 and SAE3 and the first, second and third copy pixel electrodes CPE1, CPE2 and CPE3. Each set of the sub-pixel electrode SAE1, SAE2 or SAE3, the copy pixel electrode CPE1, CPE2 or CPE3, and the bridge electrode BAP1, BAP2 or BAP3 located in the first sub-display area SDA1 may constitute substantially one same electrode (one physically connected electrode) and may include substantially a same material and cross-sectional structure. The sub-pixel electrodes SAE1 through SAE3 and the copy pixel electrodes CPE1 through CPE3 located in the first sub-display area SDA1 may be referred to as first type sub-pixel electrodes SAE #1 (or ‘first sub-pixel electrodes’) and first type copy pixel electrodes CPE #1 (or ‘first copy pixel electrodes’), respectively.

On the other hand, the fourth, fifth and sixth sub-pixel electrodes SAE4, SAE5 and SAE6 located in the second sub-display area SDA2 may be connected to the fourth, fifth and sixth copy pixel electrodes CPE4, CPE5 and CPE6 through patterns which are located in the same layer as but are separate from the fourth, fifth and sixth sub-pixel electrodes SAE4, SAE5 and SAE6 and the fourth, fifth and sixth copy pixel electrodes CPE4, CPE5 and CPE6. In the second sub-display area SDA2, a plurality of connection patterns BAP, which surround the fourth, fifth and sixth sub-pixel electrodes SAE4, SAE5 and SAE6 and the fourth, fifth and sixth copy pixel electrodes CPE4, CPE5 and CPE6, may be located. The fourth, fifth and sixth sub-pixel electrodes SAE4, SAE5 and SAE6 and the fourth, fifth and sixth copy pixel electrodes CPE4, CPE5 and CPE6 may be connected to each other by the connection patterns BAP, respectively. The sub-pixel electrodes SAE4 through SAE6 and the copy pixel electrodes CPE4 through CPE6 located in the second sub-display area SDA2 may be referred to as second type sub-pixel electrodes SAE #2 (or ‘second sub-pixel electrodes’) and second type copy pixel electrodes CPE #2 (or ‘second copy pixel electrodes’), respectively.

The first sub-pixel circuits SPC1 may be electrically connected to the sub-pixel electrodes SAE1 through SAE3, which are located in the first sub-display pixel SDX1, or the first type sub-pixel electrodes SAE #1, respectively. The first sub-pixel circuits SPC1 may be electrically connected to the first sub-pixel electrode SAE1, the second sub-pixel electrode SAE2, and the third sub-pixel electrode SAE3, respectively. The first type copy pixel electrodes CPE #1 located in the first sub-display pixel SDX1 may be electrically connected to the first type sub-pixel electrodes SAE #1 through the bridge electrodes BAP1, BAP2 and BAP3, respectively. A plurality of light emitting elements, which include a pair of a sub-pixel electrode SAE1, SAE2 or SAE3 and a copy pixel electrode CPE1, CPE2 or CPE3, may emit light simultaneously. The sub-pixel electrodes SAE1 through SAE3 located in the first sub-display pixel SDX1 may overlap the first sub-pixel circuits SPC1, respectively.

The second sub-pixel circuits SPC2 may be electrically connected to the sub-pixel electrodes SAE4 through SAE6, which are located in the second sub-display pixel SDX2, or the second type sub-pixel electrodes SAE #2, respectively. The second sub-pixel circuits SPC2 may be electrically connected to the fourth sub-pixel electrode SAE4, the fifth sub-pixel electrode SAE5, and the sixth sub-pixel electrode SAE6, respectively. The second type copy pixel electrodes CPE #2 located in the second sub-display pixel SDX2 may be electrically connected to the second type sub-pixel electrodes SAE #2 through the connection patterns BAP, respectively. A plurality of light emitting elements, which include a pair of a sub-pixel electrode SAE4, SAE5 or SAE6 and a copy pixel electrode CPE4, CPE5 or CPE6, may emit light simultaneously. In the sub-display area SDA, the connection patterns BAP, which connect the second sub-pixel circuits SPC2 and the sub-pixel electrodes SAE #2 of the second sub-display pixel SDX2, may be located. At least some of the copy pixel electrodes CPE #1 located in the first sub-display pixel SDX1 may overlap the second sub-pixel circuits SPC2. Some other ones of the copy pixel electrodes CPE #1 located in the first sub-display pixel SDX1 may be located in an area where the sub-pixel circuits SPC1 and SPC2 are not located.

According to an embodiment, the sub-pixel electrodes SAE #1, the copy pixel electrodes CPE #1, and the bridge electrodes BAP #1 located in the first sub-display area SDA1 may be located in a same layer to form integrated patterns, respectively. In an embodiment, for example, the first, second and third bridge electrodes BAP1, BAP2 and BAP3 located in the first sub-display area SDA1 may be bridge portions which are integrated (or integrally formed) with the first, second and third sub-pixel electrodes SAE1, SAE2 and SAE3 and the first, second and third copy pixel electrodes CPE1, CPE2 and CPE3, respectively. On the other hand, the sub-pixel electrodes SAE #2 and the copy pixel electrodes CPE #2 located in the second sub-display area SDA2 may be located in a same layer and have a same electrode structure as each other, but the connection patterns BAP located around them may include a different material and have a different structure from them. The connection patterns BAP located in the second sub-display area SDA2 may be located in a same layer as the sub-pixel electrodes SAE #2 and the copy pixel electrodes CPE #2 located in the second sub-display area SDA2 and may be electrically connected to the sub-pixel electrodes SAE #2 and the copy pixel electrodes CPE #2 through contact with them.

The sub-pixel electrodes SAE #1 located in the first sub-display area SDA1 may overlap the first sub-pixel circuits SPC1 and may be integrated with the copy pixel electrodes CPE #1 through the bridge electrodes BAP #1 in a same layer. The sub-pixel electrodes SAE #2 located in the second sub-display area SDA2 may be electrically connected to the second sub-pixel circuits SPC2 but may not overlap the second sub-pixel circuits SPC2. The sub-pixel electrodes SAE #2 located in the second sub-display area SDA2 may be electrically connected to the second sub-pixel circuits SPC2 through bridge electrodes located under the second sub-pixel electrodes SAE #2.

In the sub-display area SDA, the sub-pixel circuits SPC1 and SPC2 may be located only in the first sub-display area SDA1 in consideration of transmittance. Since the number of sub-pixel circuits SPC1 and SPC2 per unit area is smaller in the sub-display area SDA than in the main display area MDA, a sub-pixel electrode SAE1, SAE2, SAE3, SAE4, SAE5 or SAE6 and a copy pixel electrode CPE1, CPE2, CPE3, CPE4, CPE5 or CPE6 may form a pair to form a plurality of emission areas in the sub-display pixels SDX1 and SDX2 located in the sub-display area SDA.

The cross-sectional structures of the sub-pixel electrodes SAE #1, the copy pixel electrodes CPE #1 and the bridge electrodes BAP #1 located in the first sub-display area SDA1 and the cross-sectional structures of the sub-pixel electrodes SAE #2, the copy pixel electrodes CPE #2 and the connection patterns BAP located in the second sub-display area SDA2 will now be described with reference to FIG. 18. In FIG. 18, the first sub-pixel electrode SAE1, the first copy pixel electrode CPE1, the first bridge electrode BAP1, the fourth sub-pixel electrode SAE4, the fourth copy pixel electrode CPE4, and a connection pattern BAP are described as an example. However, the same technical spirit is applicable to the second through sixth sub-pixel electrodes SAE2 through SAE6, the second through sixth copy pixel electrodes CPE2 through CPE6, the second and third bridge electrodes BAP2 and BAP3, and other connection patterns BAP.

Referring to FIG. 18, the first sub-pixel electrode SAE1 and the first copy pixel electrode CPE1 located in the first sub-display area SDA1 may be connected to each other through the first bridge electrode BAP1. In an embodiment, for example, the first sub-pixel electrode SAE1, the first copy pixel electrode CPE1, and the first bridge electrode BAP1 may be electrodes which are integrated with each other, e.g., integrally formed with each other as a single unitary indivisible part. The first sub-pixel electrode SAE1, the first copy pixel electrode CPE1, and the first bridge electrode BAP1 may constitute substantially one same electrode (one physically connected electrode) and may include substantially a same material and cross-sectional structure.

A first sub-pixel circuit SPC1 connected to the first sub-pixel electrode SAE1 may be located in the first sub-display area SDA1. The first sub-pixel electrode SAE1 may be connected to a thin-film transistor TFT of the first sub-pixel circuit SPC1 through a second connection electrode CNE2. The first sub-pixel electrode SAE1 may overlap the first sub-pixel circuit SPC1.

On the other hand, the fourth sub-pixel electrode SAE4 and the fourth copy pixel electrode CPE4 located in the second sub-display area SDA1 may be connected to each other through a connection pattern BAP. In an embodiment, for example, the fourth sub-pixel electrode SAE4, the fourth copy pixel electrode CPE4, and the connection pattern BAP may be physically separate electrodes. The fourth sub-pixel electrode SAE4, the fourth copy pixel electrode CPE4, and the connection pattern BAP may be configured as physically separate electrodes and may include substantially different materials and cross-sectional structures.

A second sub-pixel circuit SPC2 connected to the fourth sub-pixel electrode SAE4 may be located in the first sub-display area SDA1. The fourth sub-pixel electrode SAE4 may be connected to a thin-film transistor TFT of the second sub-pixel circuit SPC2 through a bridge pattern BRE. The fourth sub-pixel electrode SAE4 may not overlap the second sub-pixel circuit SPC2.

The display device 10 according to an embodiment may include pixel transmission areas TA_P penetrating the fourth sub-pixel electrode SAE4 and the fourth copy pixel electrode CPE4. The fourth sub-pixel electrode SAE4, the fourth copy pixel electrode CPE4, light emitting layers EL, a common electrode CE, color filters CF, and a light blocking layer BM may not be located in the pixel transmission areas TA_P. The fourth sub-pixel electrode SAE4, the fourth copy pixel electrode CPE4, the light emitting layers EL, the common electrode CE, the color filters CF, and the light blocking layer BM may include openings located in the pixel transmission areas TA_P.

In some embodiments, the bridge pattern BRE overlapping a transmission area TA may be a transparent electrode. In an embodiment, for example, the bridge pattern BRE may include a transparent metal material (TCO) such as ITO or IZO. Accordingly, the transmittance of the transmission area TA can be improved.

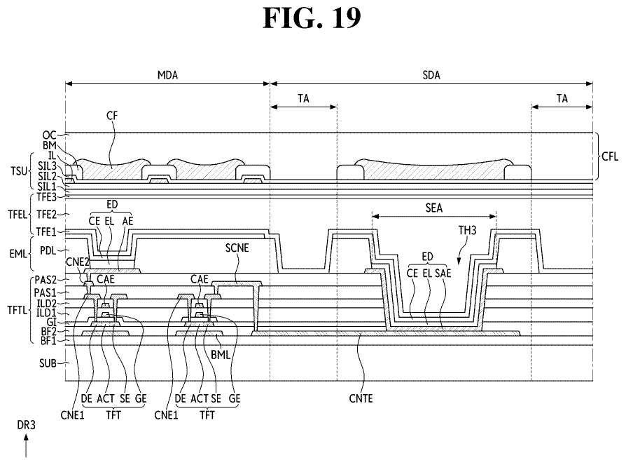

FIG. 19 is a cross-sectional view illustrating a main display area MDA and a sub-display area SDA of a display device 10 according to an embodiment.

The embodiment of the display device 10 shown in FIG. 19 is substantially the same as the display device 10 according to the embodiments described above with reference to FIGS. 13 through 18, etc. except that the display device 10 is provided with a third transmission hole TH3 and a sub-pixel electrode SAE is located in the third transmission hole TH3.

In an embodiment, the display device 10 may include the third transmission hole TH3 located in the sub-display area SDA and the concave sub-pixel electrode SAE located in the third transmission hole TH3.

The third transmission hole TH3 may penetrate or be defined through a second buffer layer BF2, a gate insulating layer GI, a first interlayer insulating layer ILD1, a second interlayer insulating layer ILD2, a first passivation layer PAS1, and a second passivation layer PAS2.

The sub-pixel electrode SAE may be located on an upper surface of the second passivation layer PAS2 and inside the third transmission hole TH3. The sub-pixel electrode SAE may be located on side surfaces of the third transmission hole TH3 and on an upper surface of a contact electrode CNTE of a bottom conductive layer which is exposed by the third transmission hole TH3. Accordingly, the sub-pixel electrode SAE may have a concave shape. The sub-pixel electrode SAE may include a flat portion on the contact electrode CNTE and an inclined portion on the side surfaces of the third transmission hole TH3.

The contact electrode CNTE may be located in the bottom conductive layer. The contact electrode CNTE may extend from the sub-display area SDA toward the main display area MDA. The contact electrode CNTE may be connected to a thin-film transistor TFT, which is located in the main display area MDA, through an inter-area connection electrode SCNE. The inter-area connection electrode SCNE may be located in a second source-drain conductive layer.

Since a pixel circuit (or a thin-film transistor TFT) connected to the sub-pixel electrode SAE is located in the main display area MDA, the transmittance of the sub-display area SDA can be improved.

In some embodiments, the contact electrode CNTE overlapping a transmission area TA may be a transparent electrode. In an embodiment, for example, the contact electrode CNTE may include a transparent metal material (TCO) such as ITO or IZO. Accordingly, the transmittance of the transmission area TA can be improved.

In the display device 10 according to an embodiment, side luminance and emission area can be improved because the sub-pixel electrode SAE includes the inclined portion in addition to the flat portion.

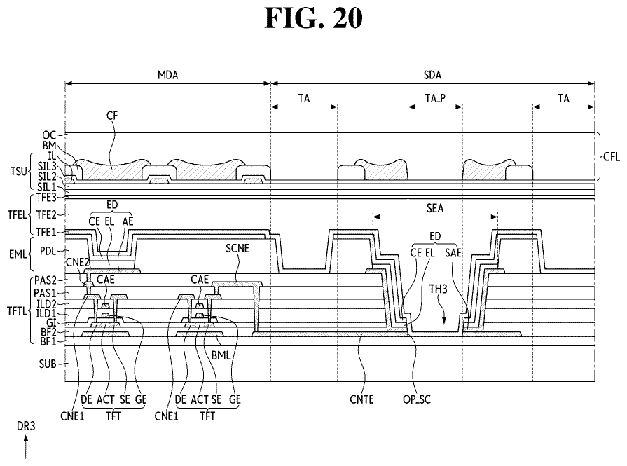

FIG. 20 is a cross-sectional view illustrating a main display area MDA and a sub-display area SDA of a display device according to an embodiment.

The embodiment of the display device 10 shown in FIG. 20 is substantially the same as the display device 10 according to the embodiment described with reference to FIG. 19 except that the display device 10 further includes a pixel transmission area TA_P overlapping a third transmission hole TH3.

In an embodiment, the display device 10 may include the pixel transmission area TA_P which penetrates a sub-pixel electrode SAE. The pixel transmission area TA_P may overlap the third transmission hole TH3. The pixel transmission area TA_P may overlap a sub-emission area SEA.

A contact electrode CNTE, the sub-pixel electrode SAE, a light emitting layer EL, a common electrode CE, and a color filter CF may not be located in the pixel transmission area TA_P. The contact electrode CNTE, the sub-pixel electrode SAE, the light emitting layer EL, the common electrode CE, and the color filter CF may include openings located in the pixel transmission area TA_P. In an embodiment, for example, the contact electrode CNTE may be provided with a seventh opening OP_SC.

Since the display device 10 according to an embodiment further includes the pixel transmission area TA_P, which overlaps the sub-emission area SEA, in the sub-display area SDA, the transmittance of the sub-display area SDA can be improved, and the uniformity of light incident on the sub-display area SDA can be improved.

A display device 10 according to embodiments described herein can be applied to various electronic devices 1. An electronic device 1 according to an embodiment includes the display device 10 and may further include modules or devices having other additional functions, in addition to the display device 10.

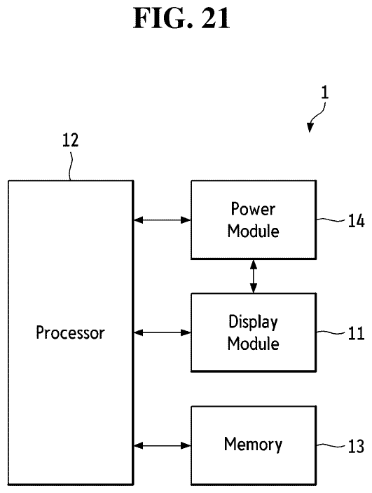

FIG. 21 is a block diagram of an electronic device 1 according to an embodiment.

Referring to FIG. 21, the electronic device 1 according to an embodiment may include a display module 11, a processor 12, a memory 13, and a power module 14.

The processor 12 may include at least one selected from a central processing unit (CPU), an application processor (AP), a graphic processing unit (GPU), a communication processor (CP), an image signal processor (ISP), and a controller.

The memory 13 may store data information used for the operation of the processor 12 or the display module 11. When the processor 12 executes an application stored in the memory 13, an image data signal and/or an input control signal may be transmitted to the display module 11. The display module 11 may process the received signal and output image information through a display screen.

The power module 14 may include a power supply module, such as a power adapter or a battery device, and a power conversion module. The power conversion module may generate the power used for the operation of the electronic device 1 by converting power supplied by the power supply module.

At least one of the elements of the electronic device 1 described above may be included in a display device 10 according to the above-described embodiments. In addition, some of individual modules functionally included in one module may be included in the display device 10, and other modules may be provided separately from the display device 10. In an embodiment, for example, the display device 10 may include the display module 11, and the processor 12, the memory 13 and the power module 14 may be provided not in the display device 10 but as other devices within the electronic device 1.

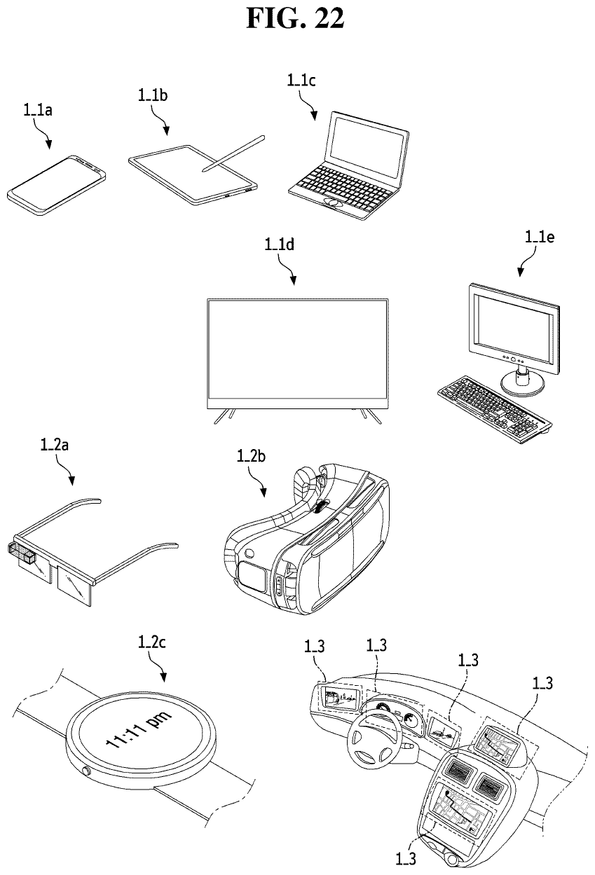

FIG. 22 is a schematic diagram of electronic devices according to various embodiments.

Referring to FIG. 22, electronic devices 1 to which a display device 10 according to embodiments is applied may include image display electronic devices 1 such as a smartphone 1_1a, a tablet personal computer (PC) 1_1b, a laptop computer 1_1c, a television 1_1d, and a desk monitor 1_1e. In addition, the various electronic devices to which the display device 10 according to embodiments is applied may include wearable electronic devices 1 including display modules, such as smart glasses 1_2a, a head mounted display 1_2b and a smart watch 1_2c, and vehicle electronic devices 1_3 including display modules, such as a center information display (CID) and a room mirror display placed on an instrument panel, center fascia and dashboard of a vehicle.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
a first display area and a second display area surrounded by the first display area;
a substrate;
a first pixel circuit and a second pixel circuit which are located on the substrate, wherein each of the first pixel circuit and the second pixel circuit comprises a thin-film transistor;
a first pixel electrode and a second pixel electrode which are located on the first pixel circuit and the second pixel circuit, respectively, and located in the first display area and the second display area, respectively;
a light emitting layer located on each of the first pixel electrode and the second pixel electrode;
a common electrode located on the light emitting layer;
a first transmission portion defined in the second display area and not overlapping the second pixel electrode; and
a second transmission portion defined through the second pixel electrode.

2. The display device of claim 1, wherein the second pixel electrode is provided with a first opening overlapping the second transmission portion.

3. The display device of claim 1, further comprising a bottom conductive layer located between the second pixel circuit and the substrate,
wherein the bottom conductive layer comprises a bottom conductive pattern overlapping the second pixel electrode, and
the bottom conductive pattern is provided with a second opening overlapping the second transmission portion.

4. The display device of claim 1, wherein the light emitting layer comprises a third opening overlapping the second transmission portion.

5. The display device of claim 1, wherein the common electrode is provided with a fourth opening overlapping the second transmission portion.

6. The display device of claim 2, further comprising a thin-film encapsulation layer located on the common electrode,
wherein the thin-film encapsulation layer covers side surfaces of the second pixel electrode within the first opening.

7. The display device of claim 1, further comprising a color filter located on the common electrode,
wherein the color filter is provided with a fifth opening overlapping the second transmission portion.

8. The display device of claim 1, wherein a density of the first pixel electrode in the first display area is higher than a density of the second pixel electrode in the second display area.

9. The display device of claim 1, further comprising at least one insulating layer located under the first pixel electrode and the second pixel electrode,
wherein the at least one insulating layer is located across the first display area and the second display area, and does not overlap the first transmission portion.

10. The display device of claim 9, wherein the at least one insulating layer is provided with a seventh opening overlapping the second transmission portion and penetrating the at least one insulating layer.

11. The display device of claim 9, further comprising a bottom conductive layer which is located between the substrate and the second pixel circuit and comprises a bottom conductive pattern located under the second pixel circuit,
wherein the at least one insulating layer is provided with a through hole overlapping the second pixel electrode and penetrating the at least one insulating layer,
the bottom conductive layer further comprises a contact electrode extending across the first display area and the second display area to overlap the second pixel electrode, and
the second pixel electrode is located within the through hole and directly contacts the contact electrode within the through hole.

12. The display device of claim 11, further comprising a source-drain conductive layer which is located between the first pixel circuit and the first pixel electrode and includes a first connection electrode connecting the first pixel circuit and the first pixel electrode,
wherein the source-drain conductive layer further comprises a second connection electrode which connects the second pixel circuit and the contact electrode.

13. The display device of claim 1, further comprising lines connected to at least one of the first pixel circuit and the second pixel circuit and extending across the first display area and the second display area,
wherein the lines do not overlap the second transmission portion.

14. The display device of claim 1, further comprising:
a pixel defining layer located on the first pixel electrode and the second pixel electrode provided with first openings which overlap the first pixel electrode and the second pixel electrode;
a light blocking layer located on the common electrode and provided with second openings which overlap the first openings; and
color filters overlapping the second openings,
wherein at least a portion of the light emitting layer is located in the first openings,
the color filters do not overlap the second transmission portion,
the light blocking layer comprises a first portion overlapping the pixel defining layer and a second portion overlapping the second pixel electrode, and
the second portion is provided with a sixth opening overlapping the second transmission portion.

15. A display device comprising:
a first display area, a second display area surrounded by the first display area, and a third display area surrounded by the second display area;
a substrate;
a first pixel circuit, a second pixel circuit and a third pixel circuit which are located on the substrate, wherein each of the first pixel circuit, the second pixel circuit and the third pixel circuit comprises a thin-film transistor;
a first pixel electrode, a second pixel electrode and a third pixel electrode which are located on the first pixel circuit, the second pixel circuit and the third pixel circuit, respectively, and located in the first display area, the second display area and the third pixel display area, respectively;
a light emitting layer located on each of the first pixel electrode, the second pixel electrode, and the third pixel electrode;
a common electrode located on the light emitting layer;
a first transmission portion defined in the third display area and not overlapping the second pixel electrode; and
a second transmission portion defined through the third pixel electrode,
wherein the first pixel circuit is located in the first display area,
the second pixel circuit and the third pixel circuit are located in the second display area,
the second pixel circuit is connected to the second pixel electrode by a first connection electrode located in the second display area, and
the third pixel circuit is connected to the third pixel electrode by a second connection electrode located across the second display area and the third display area.

16. The display device of claim 15, wherein the second pixel electrode comprises a first sub-pixel electrode and a first copy pixel electrode,
the first sub-pixel electrode and the first copy pixel electrode are connected by a first bridge electrode, and
the first sub-pixel electrode, the first copy pixel electrode and the first bridge electrode are integrally formed with each other as a single unitary indivisible part.

17. The display device of claim 15, wherein the third pixel electrode comprises a second sub-pixel electrode and a second copy pixel electrode, the second sub-pixel electrode and the second copy pixel electrode are connected by a connection pattern, and
the connection pattern is an electrode separated from the second sub-pixel electrode and the second copy pixel electrode.

18. The display device of claim 15, wherein the second connection electrode comprises a transparent electrode.

19. An electronic device comprising:
a display device; and
a processor which provides a data signal to the display device,
wherein the display device comprises:
a first display area and a second display area surrounded by the first display area;
a substrate;
a first pixel circuit and a second pixel circuit which are located on the substrate, wherein each of the first pixel circuit and the second pixel circuit comprises a thin-film transistor;
a first pixel electrode and a second pixel electrode which are located on the first pixel circuit and the second pixel circuit, respectively, and located in the first display area and the second display area, respectively;
a light emitting layer located on each of the first pixel electrode and the second pixel electrode;
a common electrode located on the light emitting layer;
a first transmission portion defined in the second display area and not overlapping the second pixel electrode; and
a second transmission portion defined through the second pixel electrode.
